(19) United States
(12) Patent Application Publication
(10) Pub. No.: US 2025/0240958 A1
(43) Pub. Date: Jul. 24, 2025

(54) INTEGRATED CIRCUIT DEVICES HAVING REFLECTIVE STRUCTURES THEREIN THAT ENHANCE DEVICE YIELD AND METHODS OF FABRICATING THE SAME

(71) Applicant: Samsung Electronics Co., Ltd., Suwon-si (KR)

(72) Inventors: Seongkeun Cho, Suwon-si (KR); Sung Gil Kim, Suwon-si (KR); Seul Ye Kim, Suwon-si (KR); Eun-Ji Kim, Suwon-si (KR); Yi Hwan Kim, Suwon-si (KR); Hyun Gang Kim, Suwon-si (KR); Je Hong Oh, Suwon-si (KR); Ji Hye Lee, Suwon-si (KR); Soochan Chung, Suwon-si (KR); Young Hwan Jo, Suwon-si (KR)

(21) Appl. No.: 18/814,840

(22) Filed: Aug. 26, 2024

(30) Foreign Application Priority Data
Jan. 24, 2024 (KR) 10-2024-0010629

(51) Int. Cl. H10B 43/27; G11C 16/04; H01L 25/065; H10B 43/10; H10B 43/35; H10B 43/40; H10B 80/00

(52) U.S. Cl. CPC H10B 43/27; G11C 16/0483; H01L 25/0652; H10B 43/10; H10B 43/35; H10B 43/40; H10B 80/00; H01L 2225/06506

(57) ABSTRACT

A method of forming an integrated circuit device includes forming a first substrate, forming a stacked structure including a plurality of spaced-apart gate electrodes sequentially stacked in a first direction, on the first substrate, forming a reflective structure including at least one first reflective layer having a first refractive index and at least one second reflective layer having a second refractive index unequal to the first refractive index, which are alternately stacked in the first direction and extend between the first substrate and the stacked structure, and forming a channel structure that extends in the first direction and passes through the stacked structure and the reflective structure, and is connected to the first substrate.

### REFERENCE TO PRIORITY APPLICATION

This application claims priority under 35 USC § 119 to Korean Patent Application No. 10-2024-0010629, filed Jan. 24, 2024, the disclosure of which is hereby incorporated herein by reference.

### BACKGROUND

The present disclosure relates to integrated circuit devices and methods of fabricating same and, more particularly, to integrated circuit memory devices and memory systems and methods of fabricating same.

As semiconductor memory devices capable of storing data of high capacity are increasingly required in electronic systems, various methods of fabricating memory devices that are capable of increasing data storage capacity have been studied. One method, which is capable of increasing the data storage capacity of a semiconductor memory device, includes the formation of highly integrated memory cells that are arranged three-dimensionally instead of memory cells that are arranged two-dimensionally.

### SUMMARY

An object of the present disclosure is to provide an integrated circuit device that has improved yield and reliability.

Another object of the present disclosure is to provide a method for fabricating an integrated circuit device having improved yield and reliability.

A further object of the present disclosure is to provide an electronic system including an integrated circuit device having improved yield and reliability.

The objects of the present disclosure are not limited to those mentioned above and additional objects of the present disclosure, which are not mentioned herein, will be clearly understood by those skilled in the art from the following description of the present disclosure.

According to an aspect of the present disclosure, a method of forming an integrated circuit device comprises forming a first substrate, forming a stacked structure including a plurality of spaced-apart gate electrodes sequentially stacked in a first direction, on the first substrate, forming a reflective structure including at least one first reflective layer having a first refractive index and at least one second reflective layer having a second refractive index unequal to the first refractive index, which are alternately stacked in the first direction and extend between the first substrate and the stacked structure, and forming a channel structure that extends in the first direction and passes through the stacked structure and the reflective structure, and is connected to the first substrate.

According to another aspect of the present disclosure, a method of forming an integrated circuit device comprises forming a substrate, forming a reflective structure on the substrate, said reflective structure including at least one first reflective layer and at least one second reflective layer that are alternately stacked, forming a mold layer on the reflective structure, and forming a semiconductor film that extends in a vertical direction, crosses an upper surface of the substrate, and fills at least a portion of a through hole passing through the mold layer, wherein a first thickness t1 of the at least one first reflective layer is selected within a range defined by Equation 1 as:

$$\frac{λ}{4 {n}_{1}} - Δ {t}_{1} \leq t 1 \leq \frac{λ}{4 {n}_{1}} + Δ {t}_{1} , where Δ {t}_{1} = \frac{1}{10} ( \frac{λ}{4 {n}_{1}} ) ;$$

wherein a second thickness t2 of the at least one second reflective layer is selected within a range defined by Equation 2 as:

$$\frac{λ}{4 {n}_{2}} - Δ {t}_{2} \leq t 2 \leq \frac{λ}{4 {n}_{2}} + Δ {t}_{2} , where Δ {t}_{2} = \frac{1}{10} ( \frac{λ}{4 {n}_{2}} ) ;$$

and wherein λ is a wavelength of light in a range from 400 nm to 700 nm during an irradiation of the reflective structure using laser annealing, n₁ represents a refractive index of the at least one first reflective layer, and n₂ represents a refractive index of the at least one second reflective layer.

According to still another aspect of the present disclosure, a method of forming an electronic system comprises forming a main board, forming a semiconductor memory device on the main substrate, said memory device including a substrate, a stacked structure including a plurality of gate electrodes sequentially stacked to be spaced apart from each other in a first direction on the substrate, a reflective structure including at least one first reflective layer having a first refractive index and at least one second reflective layer having a second refractive index unequal to the first refractive index, which are alternately stacked in the first direction between the substrate and the stacked structure, and a channel structure extended in the first direction to pass through the stacked structure and the reflective structure, and connected to the substrate, and forming a controller electrically connected to the semiconductor memory device on the main board.

### BRIEF DESCRIPTION OF THE DRAWINGS

FIG. 1 is a schematic cross-sectional view illustrating a semiconductor device according to some embodiments.

FIGS. 2 to 7 are views illustrating intermediate steps to describe a method for fabricating a semiconductor device according to some embodiments.

FIG. 8 is an example block diagram illustrating a semiconductor device according to some embodiments.

FIG. 9 is an example circuit view illustrating a semiconductor device according to some embodiments.

FIG. 10 is a layout view illustrating a semiconductor device according to some embodiments.

FIG. 11 is a cross-sectional view taken along line A-A of FIG. 10.

FIG. 12 is an enlarged view illustrating a region R1 of FIG. 11.

FIGS. 13 and 14 are various cross-sectional views illustrating a semiconductor device according to some embodiments.

FIG. 15 is a cross-sectional view illustrating a semiconductor device according to some embodiments.

FIG. 16 is an enlarged view illustrating a region R2 of FIG. 15.

FIG. 17 is a cross-sectional view illustrating a semiconductor device according to some embodiments.

FIG. 18 is an enlarged view illustrating a region R3 of FIG. 17.

FIG. 19 is a cross-sectional view illustrating a semiconductor device according to some embodiments.

FIG. 20 is an enlarged view illustrating a region R4 of FIG. 19.

FIGS. 21 to 30 are views illustrating intermediate steps to describe a method for fabricating a semiconductor device according to some embodiments.

FIG. 31 is an example block diagram illustrating an electronic system according to some embodiments.

FIG. 32 is an example perspective view illustrating an electronic system according to some embodiments.

FIG. 33 is a schematic cross-sectional view taken along line I-I of FIG. 32.

### DETAILED DESCRIPTION OF EMBODIMENTS

In the present disclosure, “same” means a fine difference that may occur due to a process margin, etc. as well as the completely same.

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

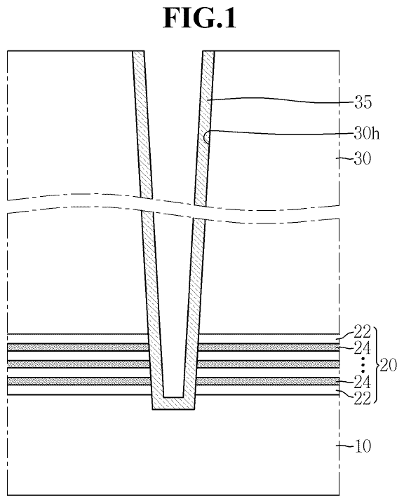

Hereinafter, a semiconductor device according to example embodiments of the present disclosure will be described with reference to FIG. 1, which provides a schematic cross-sectional view illustrating a semiconductor device according to some embodiments. Referring to FIG. 1, a semiconductor device according to some embodiments includes a substrate 10, a reflective structure 20, a mold layer 30 and a target layer 35.

The substrate 10 may include, but is not limited to, at least one of a conductive material such as metal, metal nitride, metal silicide and metal silicide nitride, an insulating material such as silicon oxide, silicon nitride and silicon oxynitride, a semiconductor material such as single crystal silicon, polysilicon, or their combination, etc. For example, the substrate 10 may include a semiconductor substrate and/or a multi-layered metal wiring formed on the semiconductor substrate.

The reflective structure 20 may be formed on a primary surface of the substrate 10. The reflective structure 20 may include a distributed Bragg reflector (DBR). For example, the reflective structure 20 may have a multi-layered structure in which at least one first reflective layer 22 and at least one second reflective layer 24 are alternately stacked. The first reflective layer 22 and the second reflective layer 24 may have their respective refractive indexes, which are different from each other. For example, the first reflective layer 22 may include a silicon oxide film, a tetraethyl orthosilicate (TEOS) film or the like, and the second reflective layer 24 may include a silicon nitride film, a hafnium oxide film or the like.

Although the reflective structure 20 is shown as including only four first reflective layers 22 and three second reflective layers 24, this is only example, and the number of layers of the first reflective layer 22 and the number of layers of the second reflective layer 24, which are included in the reflective structure 20, may vary. In addition, although it is shown that only the first reflective layer 22 is disposed at the lowermost and uppermost portions of the reflective structure 20, this is also only example, and the second reflective layer 24 may be disposed at the lowermost portion and/or the uppermost portion of the reflective structure 20. Furthermore, although the reflective structure 20 is shown as being formed directly on the substrate 10, this is only example, and another layer or element may be interposed between the substrate 10 and the reflective structure 20.

The mold layer 30 may be formed on the reflective structure 20, and the reflective structure 20 may be interposed between the substrate 10 and the mold layer 30, as shown. The mold layer 30 may include, but is not limited to, at least one of a conductive material such as metal, metal nitride, metal silicide and metal silicide nitride, an insulating material such as silicon oxide, silicon nitride and silicon oxynitride, a semiconductor material such as polysilicon, or their combination.

The target layer 35 may be formed on the substrate 10. The target layer 35 may pass through the mold layer 30. For example, a through hole 30h extended in a vertical direction crossing an upper surface of the substrate 10, passing through the mold layer 30 may be formed. The target layer 35 may fill at least a portion of the through hole 30h. For example, the target layer 35 may be extended to be conformal along a profile of the through hole 30h. The through hole 30h may have a high aspect ratio. For example, the aspect ratio of the through hole 30h may be about 10 or more, about 15 or more, or about 50 or more. In some embodiments, the aspect ratio of the through hole 30h may be about 100 or more.

In some embodiments, the target layer 35 may be connected to the substrate 10. For example, the through hole 30h may pass through the reflective structure 20 and the mold layer 30 to expose a portion of the substrate 10. A lower portion of the target layer 35 may be extended along a lower surface of the through hole 30h to contact the substrate 10. In some further embodiments, the target layer 35 may expose an upper surface of the mold layer 30. For example, the target layer 35 may not be extended along the upper surface of the mold layer 30.

Although the target layer 35 is shown as being formed directly on the reflective structure 20 and/or the mold layer 30, this is only one possible example, and another layer or element may be interposed between the reflective structure 20 and the target layer 35 and/or between the mold layer 30 and the target layer 35. The target layer 35 may include a material film which is a target of a laser annealing process. For example, the target layer 35 may include a semiconductor film, for example, a polysilicon film. In some embodiments, the target layer 35 may include a polysilicon film doped with impurities.

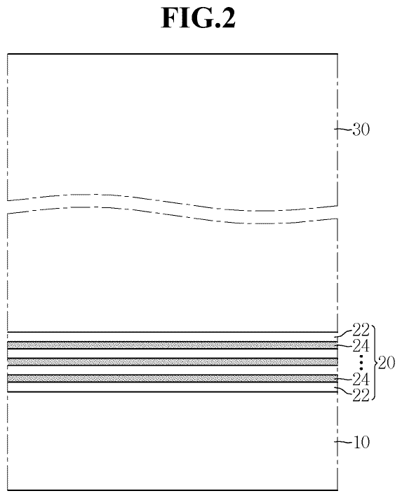

Hereinafter, a method for fabricating a semiconductor device according to example embodiments will be described with reference to FIGS. 1 to 7, where FIGS. 2 to 7 are views illustrating intermediate steps to describe a method for fabricating a semiconductor device according to some embodiments. For convenience of description, redundant portions of those described above with reference to FIG. 1 will be briefly described or omitted.

Referring to FIG. 2, a reflective structure 20 and a mold layer 30 are formed on a substrate 10. The reflective structure 20 may have a multi-layered structure in which at least one first reflective layer 22 and at least one second reflective layer 24 are alternately stacked. Each of the first reflective layer 22 and the second reflective layer 24 may be formed by, for example, a chemical vapor deposition (CVD) method, an atomic layer deposition (ALD) method or the like, but is not limited thereto. The mold layer 30 may be formed on the reflective structure 20. The mold layer 30 may be formed by, for example, a chemical vapor deposition (CVD) method, an atomic layer deposition (ALD) method or the like, but is not limited thereto.

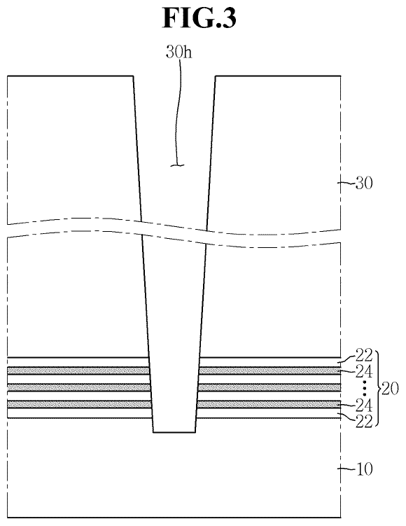

Referring to FIG. 3, a through hole 30h is formed. In some embodiments, a photolithography process may be performed for the mold layer 30. Therefore, the through hole 30h extended in a vertical direction crossing the upper surface of the substrate 10 to pass through the mold layer 30 may be formed. In some embodiments, the through hole 30h may further pass through the reflective structure 20 below the mold layer 30 to expose a portion of the substrate 10.

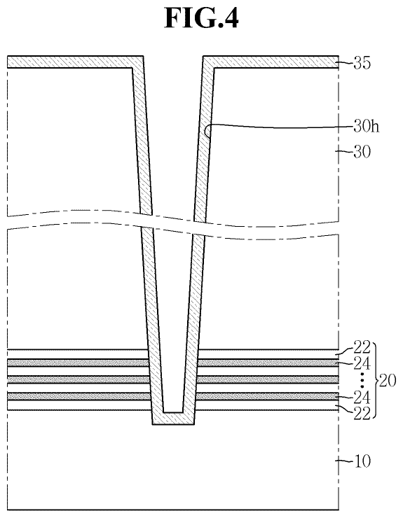

Referring to FIG. 4, a target layer 35 is formed. The target layer 35 may fill at least a portion of the through hole 30h. For example, the target layer 35 may be extended to be conformal along a profile of the upper surface of the substrate 10, sides of the reflective structure 20, and sides and an upper surface of the mold layer 30.

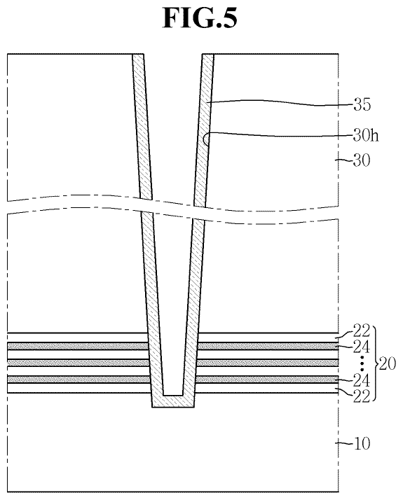

Referring to FIG. 5, a portion of the target layer 35 on the upper surface of the mold layer 30 is removed. For example, a planarization process such as a chemical mechanical polishing process may be performed. As the planarization process is performed, the upper surface of the mold layer 30 may be exposed.

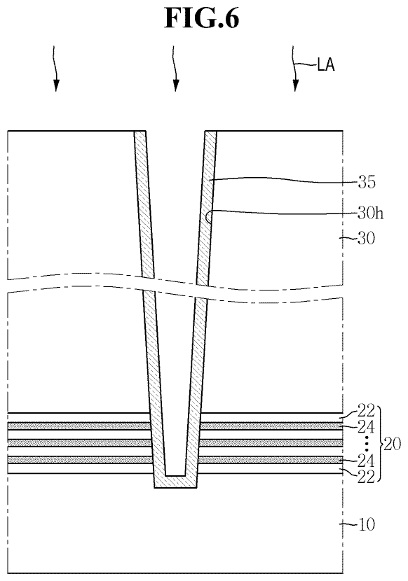

Referring to FIG. 6, a laser annealing process LA is performed for the target layer 35. As the laser annealing process LA is performed, crystallization of the target layer 35 may be induced or characteristics of a material included in the target layer 35 may be improved. Advantageously, when the target layer 35 includes a polysilicon film doped with impurities, the laser annealing process LA may increase a grain size of the target layer 35, or may improve electrical characteristics of the target layer 35 by activating the doped impurities.

In some embodiments, the laser annealing process LA may use a visible laser. For example, a wavelength λ of a laser used in the laser annealing process LA may range from about 400 nm to about 700 nm. In some embodiments, an energy density of the laser used in the laser annealing process LA may be about 50 mj/cm² to about 2,000 mj/cm². In some embodiments, the energy density of the laser used in the laser annealing process LA may be about 200 mj/cm² to about 1,200 mj/cm², where “mj” corresponds to millijoules of energy.

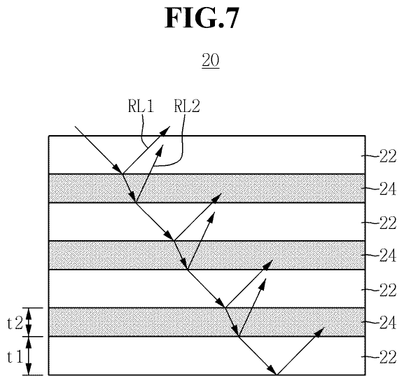

In the laser annealing process LA, the reflective structure 20 may provide high reflectance and low transmittance by using constructive interference of Fresnel reflection. For example, as shown in FIG. 7, the reflective structure 20 may include a first reflective layer 22 and a second reflective layer 24, which are alternately stacked. A first refractive index of the first reflective layer 22 may be lower than a second refractive index of the second reflective layer 24. For example, the first reflective layer 22 may include a silicon oxide film, and the second reflective layer 24 may include a silicon nitride film. In this case, first reflective light RL1 generated from a surface (e.g., upper surface) of the second reflective layer 24 may constitute constructive interference with the second reflective light RL2 generated from a surface (e.g., upper surface) of the first reflective layer 22. Therefore, the reflective structure 20 may block the laser incident on the substrate 10 and reflect the laser toward the target layer 35, thereby improving a light absorption rate below the target layer 35 having a high aspect ratio.

In order to induce the constructive interference, a first thickness t1 of the first reflective layer 22 and a second thickness t2 of the second reflective layer 24 may be appropriately selected depending on the wavelength of the laser used in the laser annealing process LA. For example, when a visible laser is used in the laser annealing process LA, the first thickness t1 of the first reflective layer 22 may be about 75 nm to about 105 nm, and the second thickness t2 of the second reflective layer 24 may be about 55 nm to about 75 nm. In the above range, high reflectance and low transmittance according to the constructive interference may be provided.

When the first refractive index of the first reflective layer 22 is less than the second refractive index of the second reflective layer 24, the first thickness t1 of the first reflective layer 22 may be greater than the second thickness t2 of the second reflective layer 24. In some embodiments, the first thickness t1 of the first reflective layer 22 may be selected within a range defined by Equation 1 below, and the second thickness t2 of the second reflective layer 24 may be selected within a range defined by Equation 2 below.

$$\frac{λ}{4 {n}_{1}} - Δ {t}_{1} \leq t 1 \leq \frac{λ}{4 {n}_{1}} + Δ {t}_{1} , where Δ {t}_{1} = \frac{1}{10} ( \frac{λ}{4 {n}_{1}} ) ; \qquad Equation 1$$

$$\frac{λ}{4 {n}_{2}} - Δ {t}_{2} \leq t 2 \leq \frac{λ}{4 {n}_{2}} + Δ {t}_{2} , where Δ {t}_{2} = \frac{1}{10} ( \frac{λ}{4 {n}_{2}} ) . \qquad Equation 2$$

In the Equations 1 and 2, λ represents a wavelength of light (laser) irradiated to the reflective structure 20 during the laser annealing process LA, n₁ represents the first refractive index of the first reflective layer 22, and n₂ represents the second refractive index of the second reflective layer 24.

For example, the wavelength λ of the laser used in the laser annealing process LA may be about 532 nm in some embodiments. Also, at the wavelength λ of the laser, the first refractive index n₁ of the first reflective layer 22 including a silicon oxide film may be about 1.46, and the second refractive index n₂ of the second reflective layer 24 including a silicon nitride film may be about 2.02. In this case, the first thickness t1 of the first reflective layer 22 may be about 82 nm to about 100 nm, and the second thickness t2 of the second reflective layer 24 may be about 60 nm to about 72 nm. In some embodiments, the reflective structure 20 may include at least three pairs of first reflective layers 22 and second reflective layers 24. In this case, the constructive interference may be induced more effectively.

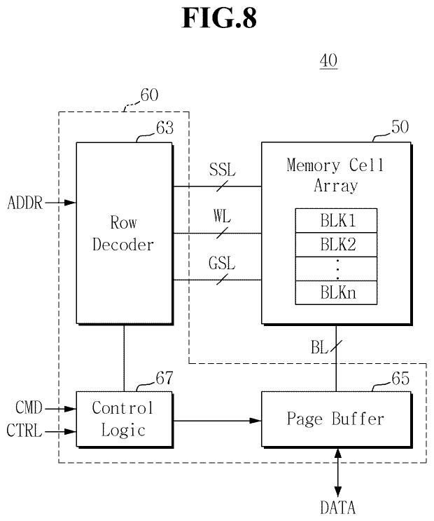

Hereinafter, the semiconductor device according to example embodiments will be described with reference to FIGS. 8 to 20. In the following description, a NAND flash memory device will be mainly described as the semiconductor device according to the example embodiments, but this is only example. As another example, the semiconductor device according to example embodiments may be a nonvolatile memory device such as a phase-change random access memory (PRAM), a magnetoresistive random access memory (MRAM), a ferroelectric random access memory (FeRAM) or a resistive random access memory (RRAM), a volatile memory device such as a dynamic random access memory (DRAM) or a static random access memory (SRAM), or a logic device such as a central processing unit (CPU), a graphic processing unit (GPU), a controller, an application specific integrated circuit (ASIC) and an application processor (AP).

FIG. 8 is an example block diagram illustrating a semiconductor device according to some embodiments. A memory cell array 50 may include a plurality of memory cell blocks BLK1 to BLKn. Each of the memory cell blocks BLK1 to BLKn may include a plurality of memory cells. The memory cell array 50 may be connected to a peripheral circuit 60 through a bit line BL, a word line WL, at least one string selection line SSL and at least one ground selection line GSL. In detail, the memory cell blocks BLK1 to BLKn may be connected to a row decoder 63 through the word line WL, the string selection line SSL and the ground selection line GSL. In addition, the memory cell blocks BLK1 to BLKn may be connected to a page buffer 65 through the bit line BL.

The peripheral circuit 60 may receive an address ADDR, a command CMD and a control signal CTRL from the outside of a semiconductor device 40, and may transmit and receive data to and from an external device of the semiconductor device 40. The peripheral circuit 60 may include a control logic 67, a row decoder 63 and a page buffer 65. Although not shown, the peripheral circuit 60 may further include various sub-circuits such as an input/output circuit, a voltage generating circuit for generating various voltages required for an operation of the semiconductor device 40 and an error correction circuit for correcting an error of the data read from the memory cell array 50.

The control logic 67 may be connected to the row decoder 63, the input/output circuit and the voltage generating circuit. The control logic 67 may control the overall operation of the semiconductor device 40. The control logic 67 may generate various internal control signals used in the semiconductor device 40 in response to the control signal CTRL. For example, the control logic 67 may adjust a voltage level provided to the word line WL and the bit line BL when a memory operation such as a program operation or an erase operation is performed.

The row decoder 63 may select at least one of the plurality of memory cell blocks BLK1 to BLKn in response to the address ADDR, and may select at least one word line WL, at least one string selection line SSL and at least one ground selection line GSL of the selected memory cell blocks BLK1 to BLKn. In addition, the row decoder 63 may transfer a voltage for performing the memory operation to the word line WL of the selected memory cell blocks BLK1 to BLKn.

The page buffer 65 may be connected to the memory cell array 50 through the bit line BL. The page buffer 65 may operate as a write driver or a sense amplifier. In detail, when a program operation is performed, the page buffer 65 may operate as a write driver to apply a voltage according to the data to be stored in the memory cell array 50, to the bit line BL. Meanwhile, when a read operation is performed, the page buffer 65 may operate as a sense amplifier to sense the data stored in the memory cell array 50.

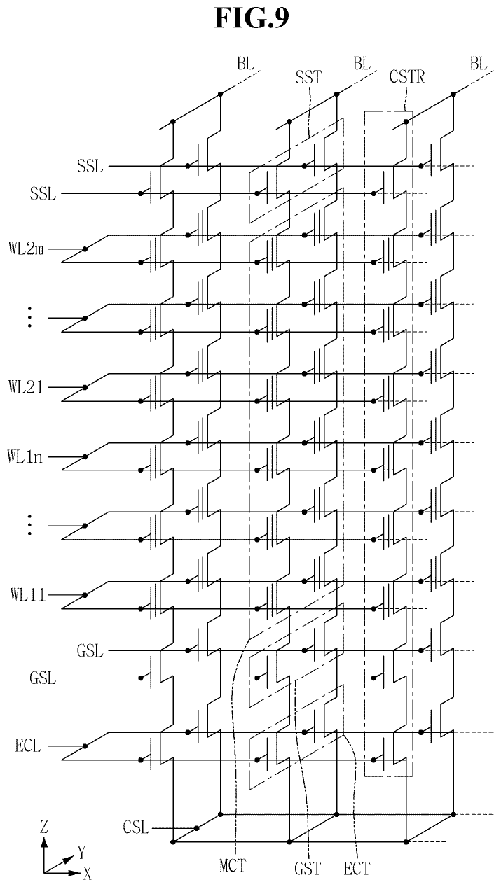

FIG. 9 is an example circuit view illustrating a semiconductor device according to some embodiments. A memory cell array (e.g., 20 of FIG. 8) of the semiconductor device according to some embodiments includes a common source line CSL, a plurality of bit lines BL and a plurality of cell strings CSTR. The plurality of bit lines BL may be arranged two-dimensionally on a plane including a first direction X and a second direction Y. For example, the bit lines BL may be respectively extended in the second direction Y, and may be spaced apart from each other and then arranged along the first direction X. The plurality of cell strings CSTR may be connected to the respective bit lines BL in parallel. The cell strings CSTR may be commonly connected to the common source line CSL. That is, the plurality of cell strings CSTR may be disposed between the bit lines BL and the common source line CSL.

Each of the cell strings CSTR may include a ground selection transistor GST connected to the common source line CSL, a string selection transistor SST connected to the bit line BL and a plurality of memory cell transistors MCT disposed between the ground selection transistor GST and the string selection transistor SST. Each of the memory cell transistors MCT may include a data storage element. The ground selection transistor GST, the string selection transistor SST and the memory cell transistors MCT may be connected in series in a vertical direction (hereinafter, referred to as a third direction Z) orthogonal to the first direction X and the second direction Y.

The common source line CSL may be commonly connected to sources of the ground selection transistors GST. In addition, the ground selection line GSL, a plurality of word lines WL11 to WL1n and WL21 to WL2m and the string selection line SSL may be disposed between the common source line CSL and the bit line BL. The ground selection line GSL may be used as a gate electrode of the ground selection transistor GST, the word lines WL11 to WL1n may be used as gate electrodes of the memory cell transistors MCT, and the string selection line SSL may be used as a gate electrode of the string selection transistor SST.

In some embodiments, an erase control transistor ECT may be disposed between the common source line CSL and the ground selection transistor GST. The common source line CSL may be commonly connected to sources of the erase control transistors ECT. An erase control line ECL may be disposed between the common source line CSL and the ground selection line GSL. The erase control line ECL may be used as a gate electrode of the erase control transistor ECT. The erase control transistors ECT may generate a gate induced drain leakage (GIDL) to perform an erase operation of the memory cell array.

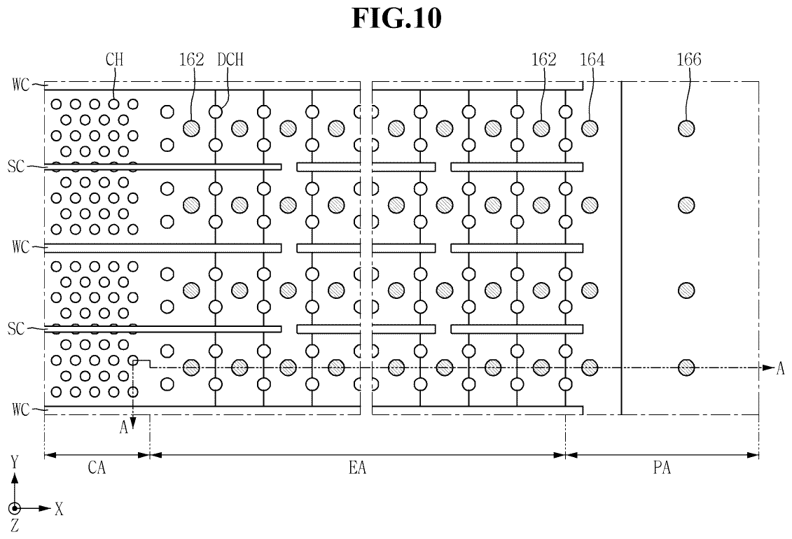

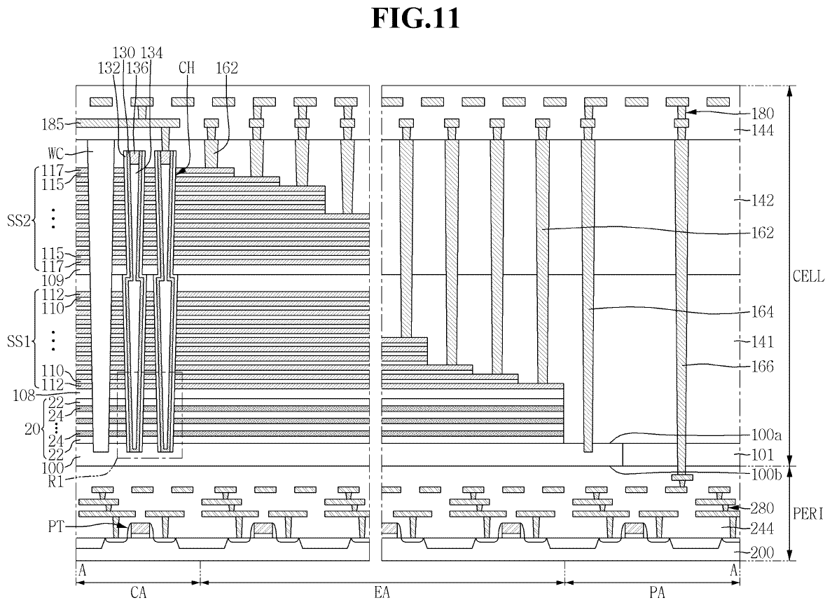

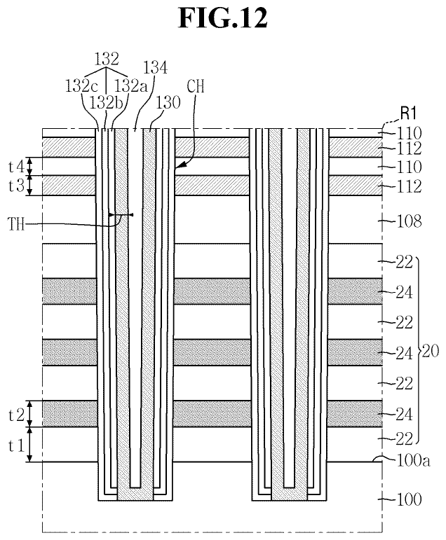

FIG. 10 is a layout view illustrating a semiconductor device according to some embodiments. FIG. 11 is a cross-sectional view taken along line A-A of FIG. 10. FIG. 12 is an enlarged view illustrating a region R1 of FIG. 11. Referring to FIGS. 10 to 12, the semiconductor device according to some embodiments includes a memory cell structure CELL and a peripheral circuit structure PERI. The memory cell structure CELL may include a cell array area CA, an extension area EA and an outer area PA. A memory cell array (e.g., 50 of FIG. 8) including a plurality of memory cells may be formed in the cell array area CA. For example, a first substrate 100, a channel structure CH, gate electrodes 112 and 117 and a conductive line 185, which will be described later, may be disposed in the cell array area CA.

The extension area EA may be disposed near the cell array area CA. For example, the extension area EA may be adjacent to the cell array area CA in the first direction X. The gate electrodes 112 and 117, which will be described later, may be stacked in the extension area EA in a stepwise shape, and a gate contact 162, which will be described later, may be disposed in the extension area EA.

The outer area PA may be a peripheral area surrounding the cell array area CA and the extension area EA. For example, the outer area PA may be adjacent to the cell array area CA and/or the extension area EA in the first direction X and/or the second direction Y. A source contact 164 and/or a through via 166, which will be described later, may be disposed in the outer area PA.

The memory cell structure CELL may include a first substrate 100, an insulating substrate 101, a reflective structure 20, a first stacked structure SS1, a first interlayer insulating film 141, a second stacked structure SS2, a second interlayer insulating film 142, a channel structure CH, a cutting pattern WC, a gate contact 162, a source contact 164, a through via 166, and a first wiring structure 180.

The first substrate 100 may include a semiconductor substrate such as, for example, a silicon substrate, a germanium substrate or a silicon-germanium substrate. Alternatively, the first substrate 100 may include a silicon-on-insulator (SOI) substrate or a germanium-on-insulator (GOI) substrate. In some embodiments, the first substrate 100 may include a conductive layer. The conductive layer may include, for example, polysilicon doped with impurities, metal or metal silicide. The conductive layer may be formed of a single layer, or may be formed of multiple layers. For example, the first substrate 100 may be an n-type substrate that includes n-type impurities (e.g., phosphorus (P), arsenic (As), etc.). For another example, the first substrate 100 may include a first conductive layer including metal silicide such as tungsten silicide (WSi), and a second conductive layer stacked on the first conductive layer, including polysilicon doped with impurities. The first substrate 100 may be provided as the common source line (e.g., CSL of FIG. 9) of the semiconductor device according to some embodiments. The first substrate 100 may include a first surface 100a and a second surface 100b, which are opposite to each other. Each of the first surface 100a and the second surface 100b may be extended along a horizontal plane (e.g., XY plane). In the following description, the first surface 100a may be also referred to as a front side of the first substrate 100, and the second surface 100b may also be referred to as a back side of the first substrate 100.

The insulating substrate 101 may be formed in at least a portion of the first substrate 100 of the extension area EA and/or the outer area PA. The insulating substrate 101 may form an insulating area in the first substrate 100 of the extension area EA and/or the outer area PA. The insulating substrate 101 may include at least one of, for example, silicon oxide, silicon nitride, silicon oxynitride or silicon carbide, but is not limited thereto.

The reflective structure 20 may be formed on the first surface 100a of the first substrate 100. At least a portion of the reflective structure 20 may be disposed in the cell array area CA. For example, the reflective structure 20 may overlap the first substrate 100 of the cell array area CA. In this case, the term “overlap” means overlap in the third direction Z.

In some embodiments, the reflective structure 20 may be disposed in the cell array area CA and the extension area EA. Although the reflective structure 20 is shown as completely covering the cell array area CA and the extension area EA, this is only example. As another example, the reflective structure 20 may be disposed in a portion of the cell array area CA and/or a portion of the extension area EA. In some embodiments, the reflective structure 20 may be disposed outside the extension area EA. For example, the reflective structure 20 may expose the first substrate 100 of the extension area EA and the insulating substrate 101 of the extension area EA.

The reflective structure 20 may include a distributed Bragg reflector (DBR). The reflective structure 20 may provide high reflectance and low transmittance by using constructive interference of Fresnel reflection. For example, the reflective structure 20 may have a multi-layered structure in which at least one first reflective layer 22 and at least one second reflective layer 24, which have their respective refractive indexes different from each other, are alternately stacked. The reflective structure 20 is similar to that described above with reference to FIGS. 1 to 7 and thus its detailed description will be omitted below. In some embodiments, at least one first reflective layer 22 may include a silicon oxide film, and at least one second reflective layer 24 may include a silicon nitride film.

In order to induce the constructive interference, the first thickness t1 of the first reflective layer 22 and the second thickness t2 of the second reflective layer 24 may be appropriately selected. For example, the first thickness t1 of the first reflective layer 22 may be selected within the range defined by Equation 1 (highlighted above), and the second thickness t2 of the second reflective layer 24 may be selected within the range defined by Equation 2 (highlighted above).

The first stacked structure SS1 may be formed on the reflective structure 20. The reflective structure 20 may be interposed between the first substrate 100 and the first stacked structure SS1. For example, a first base insulating film 108 may be formed on the reflective structure 20. The first stacked structure SS1 may include a plurality of first mold insulating films 110 and a plurality of first gate electrodes 112, which are alternately stacked on the first base insulating film 108. Each of the first mold insulating films 110 and each of the first gate electrodes 112 may have a layered structure in which they are extended along a horizontal plane (e.g., XY plane). The first gate electrodes 112 may be sequentially stacked to be spaced apart from each other by the first mold insulating films 110. The first gate electrodes 112 of the extension area EA may be stacked in a stepwise shape. For example, in the extension area EA, a length of the first gate electrodes 112 extended in the first direction X may be reduced as the first gate electrodes 112 become far away from the first base insulating film 108 is increased.

In some embodiments, the first gate electrodes 112 may include at least one erase control line (e.g., ECL of FIG. 9), at least one ground selection line (e.g., GSL of FIG. 9) and a plurality of first word lines (e.g., WL11 to WL1n of FIG. 9), which are sequentially stacked on the first base insulating film 108. The number and shape of the first mold insulating films 110 and the first gate electrodes 112 are only example, and are not limited to the shown example.

The first interlayer insulating film 141 may be formed on the first substrate 100, the insulating substrate 101, the reflective structure 20 and the first stacked structure SS1. The first interlayer insulating film 141 may cover the first stacked structure SS1. The first interlayer insulating film 141 may include at least one of, for example, silicon oxide, silicon oxynitride and/or a low dielectric constant (low-k) material having a dielectric constant lower than that of silicon oxide, but is not limited thereto.

The second stacked structure SS2 may be formed on the first interlayer insulating film 141. For example, a second base insulating film 109 may be formed on the first interlayer insulating film 141. The second stacked structure SS2 may include a plurality of second mold insulating films 115 and a plurality of second gate electrodes 117, which are alternately stacked on the second base insulating film 109. Each of the second mold insulating films 115 and each of the second gate electrodes 117 may have a layered structure in which they are extended along a horizontal plane (e.g., XY plane). The second gate electrodes 117 may be sequentially stacked to be spaced apart from each other by the second mold insulating films 115.

The second gate electrodes 117 of the extension area EA may be stacked on the second base insulating film 109 in a stepwise shape. For example, in the extension area EA, a length of the second gate electrodes 117 extended in the first direction X may be reduced as the second gate electrodes 117 become far away from the second base insulating film 109.

In some embodiments, the second gate electrodes 117 may include a plurality of second word lines (e.g., WL21 to WL2m of FIG. 9) and at least one string selection line (e.g., SSL of FIG. 9), which are sequentially stacked on the second base insulating film 109. The number and shape of the second mold insulating films 115 and the second gate electrodes 117 are only example, and are not limited to the shown example.

The second interlayer insulating film 142 may be formed on the first interlayer insulating film 141 and the second stacked structure SS2. The second interlayer insulating film 142 may cover the second stacked structure SS2. The second interlayer insulating film 142 may include at least one of, for example, silicon oxide, silicon oxynitride and/or a low dielectric constant (low-k) material having a dielectric constant lower than that of silicon oxide, but is not limited thereto.

Each of the gate electrodes 112 and 117 may include a conductive material, for example, metal such as tungsten (W), molybdenum (Mo), ruthenium (Ru), cobalt (Co) and nickel (Ni) or a semiconductor material such as silicon, but is not limited thereto. For example, each of the gate electrodes 112 and 117 may include at least one of tungsten (W), molybdenum (Mo) and/or ruthenium (Ru). For another example, each of the gate electrodes 112 and 117 may include polysilicon. Each of the mold insulating films 110 and 115 may include at least one of, for example, silicon oxide, silicon nitride and/or silicon oxynitride, but is not limited thereto. For example, each of the mold insulating films 110 and 115 may include a silicon oxide film.

The channel structure CH may be disposed in the cell array area CA. The channel structure CH may be extended in the third direction Z to pass through the stacked structures SS1 and SS2. The channel structure CH may cross the plurality of gate electrodes 112 and 117. For example, the channel structure CH may be a pillar-shaped structure (e.g., a cylinder-shaped structure) extended in the third direction Z.

In some embodiments, the channel structure CH may be connected to the first substrate 100 by passing through the reflective structure 20. For example, a lower surface of the channel structure CH may be formed to be lower than or equal to the first surface 100a of the first substrate 100. In some embodiments, a plurality of channel structures CH may be arranged in a zigzag shape. For example, as shown in FIG. 10, the channel structures CH may be arranged alternately with each other in the first direction X and the second direction Y. The channel structures CH may further improve the integration degree of the semiconductor device. The number and arrangement of the channel structures CH are only example, and are not limited to the shown example.

In some embodiments, each of the channel structures CH may have a step difference between the first stacked structure SS1 and the second stacked structure SS2. For example, as shown in FIG. 11, the sides of each of the channel structures CH may have a bending portion at a boundary between the first interlayer insulating film 141 and the second base insulating film 109. Each of the channel structures CH may include a semiconductor film 130 and a data storage film 132.

The semiconductor film 130 may be extended in the third direction Z to cross the plurality of gate electrodes 112 and 117. Although the semiconductor film 130 is shown as having only a cup shape, this is only example. For example, the semiconductor film 130 may have various shapes such as a cylindrical shape, a quadrangular barrel shape and a filled pillar shape. The semiconductor film 130 may include, for example, a semiconductor material such as monocrystalline silicon, polycrystalline silicon (polysilicon), an organic semiconductor material and a carbon nanostructure, but is not limited thereto. In some embodiments, the semiconductor film 130 may include a polysilicon film.

The data storage film 132 may be interposed between the semiconductor film 130 and the plurality of gate electrodes 112 and 117. For example, the data storage film 132 may be extended along an outer side of the semiconductor film 130. For example, the data storage film 132 may include at least one of silicon oxide, silicon nitride, silicon oxynitride or a high dielectric constant material having a dielectric constant higher than that of silicon oxide, but is not limited thereto. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide or their combination.

In some embodiments, the data storage film 132 may be formed of multiple layers. For example, as shown in FIG. 12, the data storage film 132 may include a tunnel insulating film 132a, a charge storage film 132b and a blocking insulating film 132c, which are sequentially stacked on the outer side of the semiconductor film 130. The tunnel insulating film 132a may include, for example, silicon oxide or a high dielectric constant material (e.g., aluminum oxide (Al₂O₃) or hafnium oxide (HfO₂)) having a dielectric constant higher than that of silicon oxide. The charge storage film 132b may include, for example, silicon nitride. The blocking insulating film 132c may include, for example, silicon oxide or a high dielectric constant material (e.g., aluminum oxide (Al₂O₃) or hafnium oxide (HfO₂)) having a dielectric constant higher than that of silicon oxide.

In some embodiments, the semiconductor film 130 may be electrically connected to the first substrate 100. For example, the data storage film 132 may be extended between the semiconductor film 130 and the reflective structure 20. One end (e.g., lower end) of the semiconductor film 130 may be in contact with the first substrate 100 by passing through a lower portion of the data storage film 132.

In some embodiments, the channel structure CH may further include a filling insulating film 134. The filling insulating film 134 may be formed to fill the inside of the cup-shaped semiconductor film 130. The filling insulating film 134 may include an insulating material, for example, silicon oxide, but is not limited thereto. In some embodiments, the channel structure CH may further include a channel pad 136. The channel pad 136 may be electrically connected to the other end (e.g., upper end) of the semiconductor film 130. The channel pad 136 may include a conductive material, for example, polysilicon doped with impurities, metal or metal silicide, but is not limited thereto.

In some embodiments, a dummy channel structure DCH may be formed in the extension area EA. The dummy channel structure DCH may be extended in the third direction Z to pass through at least a portion of the stacked structures SS1 and SS2. The dummy channel structure DCH may be formed at the same level as the channel structure CH, or may be formed at a different level from the channel structure CH. For example, when the dummy channel structure DCH is formed at the same level as the channel structure CH, the dummy channel structure DCH may include the semiconductor film 130, the data storage film 132, the filling insulating film 134 and the channel pad 136. For another example, when the dummy channel structure DCH is formed at a different level from the channel structure CH, the dummy channel structure DCH may be filled with an insulating material and/or a conductive material. A size, such as a width, of the dummy channel structure DCH may be the same as that of the channel structure CH, or may be different from that of the channel structure CH. In some embodiments, the size of the dummy channel structure DCH may be larger than that of the channel structure CH.

A cutting pattern WC may be formed over the cell array area CA and the extension area EA. The cutting pattern WC may be extended to be long in the first direction X to cut the stacked structures SS1 and SS2. Also, a plurality of cutting patterns WC may be spaced apart from each other in the second direction Y and extended in parallel in the first direction X. The stacked structures SS1 and SS2 may be divided by the plurality of cutting patterns WC to form a plurality of memory cell blocks (e.g., BLK1 to BLKn of FIG. 8). For example, two adjacent cutting patterns WC may define one memory cell block therebetween. A plurality of channel structures CH may be disposed in each of the memory cell blocks defined by the cutting patterns WC.

In some embodiments, the cutting pattern WC may include at least one of an insulating material, for example, silicon oxide, silicon nitride and/or silicon oxynitride, but is not limited thereto. For example, the cutting pattern WC may include a silicon oxide film. In some embodiments, a separation pattern SC may be formed in the second stacked structure SS2. The separation pattern SC may be extended in the first direction X to cut a string selection line (SSL of FIG. 9, for example, a gate electrode disposed at an uppermost portion of the second gate electrodes 117) of the second stacked structure SS2. Each of the memory cell blocks defined by the cutting patterns WC may be divided by the separation pattern SC to form a plurality of string areas. For example, the separation pattern SC may define two string areas in one memory cell block. The separation pattern SC may include at least one of an insulating material, for example, silicon oxide, silicon nitride and/or silicon oxynitride, but is not limited thereto.

The gate contact 162 may be disposed in the extension area EA. A plurality of gate contacts 162 may be electrically connected to a plurality of corresponding gate electrodes 112 and 117. For example, each of the gate contacts 162 may be extended in the third direction Z to pass through the first interlayer insulating film 141 and/or the second interlayer insulating film 142, and may be connected to a corresponding one of the gate electrodes 112 and 117. In some embodiments, a width of the gate contact 162 may be reduced toward the gate electrodes 112 and 117. The source contact 164 may be disposed in the outer area PA. The source contact 164 may be extended in the third direction Z to pass through the first interlayer insulating film 141 and the second interlayer insulating film 142, and may be connected to the first substrate 100. In some embodiments, a width of the source contact 164 may be reduced as the source contact 164 is directed toward the first substrate 100.

The through via 166 may be disposed in the outer area PA. The through via 166 may be extended in the third direction Z to pass through the insulating substrate 101, the first interlayer insulating film 141 and the second interlayer insulating film 142. In some embodiments, a width of the through via 166 may be reduced as the through via 166 is directed toward the peripheral circuit structure PERI. The first wiring structure 180 may be formed on the second interlayer insulating film 142. The first wiring structure 180 may be electrically connected to the channel structure CH, the gate contact 162, the source contact 164 and/or the through via 166. For example, a first inter-wire insulating film 144 may be formed on the second interlayer insulating film 142. The first wiring structure 180 may be formed in the first inter-wire insulating film 144 and thus connected to the channel structure CH, the gate contact 162, the source contact 164 and/or the through via 166. The number of layers and arrangement of the first wiring structure 180 are only example, and are not limited to the shown example.

The first wiring structure 180 may include at least one of a conductive material, for example, aluminum (Al), copper (Cu), tungsten (W), molybdenum (Mo), cobalt (Co), ruthenium (Ru) or their alloy, but is not limited thereto. For example, the first wiring structure 180 may include a copper (Cu) wiring. In some embodiments, the first wiring structure 180 may include a conductive line 185 disposed within the cell array area CA. The conductive line 185 may be extended to be long in the second direction Y. Also, a plurality of conductive lines 185 may be spaced apart from each other in the first direction X and thus extended in parallel in the second direction Y.

The conductive line 185 may be electrically connected to a plurality of channel structures CH arranged along the second direction Y. For example, the conductive line 185 may be connected to the other end (e.g., upper end) of the semiconductor film 130 through the channel pad 136 of the channel structure CH. The conductive line 185 may be provided as the bit line (e.g., BL of FIG. 8) of the semiconductor device according to some embodiments.

The peripheral circuit structure PERI may include a second substrate 200, a peripheral circuit element PT and a second wiring structure 280. The second substrate 200 may include, for example, a semiconductor substrate such as a silicon substrate, a germanium substrate or a silicon-germanium substrate. Alternatively, the second substrate 200 may include a silicon-on-insulator (SOI) substrate or a germanium-on-insulator (GOI) substrate.

The peripheral circuit element PT may be formed on the second substrate 200. The peripheral circuit element PT may constitute a peripheral circuit (e.g., 60 of FIG. 8) that controls an operation of a semiconductor memory device. For example, the peripheral circuit element PT may include a control logic (e.g., 67 of FIG. 8), a row decoder (e.g., 63 of FIG. 8), a page buffer (e.g., 65 of FIG. 8) and the like. In the following description, a surface of the second substrate 200 on which the peripheral circuit element PT is disposed may be referred to as a front side of the second substrate 200. In contrast, a surface of the second substrate 200 opposite to a front surface of the second substrate 200 may be referred to as a back side of the second substrate 200. The peripheral circuit element PT may include, for example, a transistor, but is not limited thereto. For example, the peripheral circuit element PT may include not only various active elements such as a transistor, but also various passive elements such as a capacitor, a register and an inductor.

The second wiring structure 280 may be formed on the peripheral circuit element PT. For example, a second inter-wiring insulating film 244 may be formed on the entire surface of the second substrate 200. The second wiring structure 280 may be formed in the second inter-wiring insulating film 244 and thus electrically connected to the peripheral circuit element PT. The number of layers and arrangement of the second wiring structure 280 are only example, and are not limited to the shown example.

In some embodiments, the memory cell structure CELL may be stacked on the peripheral circuit structure PERI. For example, the memory cell structure CELL may be stacked on the second inter-wire insulating film 244.

In some embodiments, the second surface 100b of the first substrate 100 may face the peripheral circuit structure PERI. For example, the first substrate 100 may be interposed between the stacked structures SS1 and SS2 and the peripheral circuit structure PERI.

The through via 166 may be extended in the third direction Z to electrically connect the first wiring structure 180 with the second wiring structure 280. Therefore, a plurality of memory cells formed in the cell array area CA may be electrically connected to the peripheral circuit element PT.

In order to activate the semiconductor film 130 provided as a channel of the semiconductor device, a laser annealing process for the semiconductor film 130 may be performed. However, in case of the semiconductor film 130 having a high aspect ratio, a light absorption rate may be deteriorated below the semiconductor film 130, and thus there is a problem that an activation difference occurs between a lower portion of the semiconductor film 130 and an upper portion of the semiconductor film 130. Advantageously, the semiconductor device according to some embodiments may improve the light absorption rate below the semiconductor film 130 having a high aspect ratio by using the reflective structure 20. In detail, as described above, the reflective structure 20 may be disposed between the first substrate 100 and the stacked structures SS1 and SS2. The reflective structure 20 may prevent a laser from being absorbed into the first substrate 100 by blocking the laser incident on the first substrate 100 during the laser annealing process, and may improve the light absorption rate below the semiconductor film 130 by reflecting the laser toward the semiconductor film 130. Therefore, a semiconductor device with improved yield and reliability may be provided. In some embodiments, a thickness (e.g., TH of FIG. 12) of the semiconductor film 130 may be about 5 nm to about 10 nm. In the above range, the light absorption rate may be further improved below the semiconductor film 130.

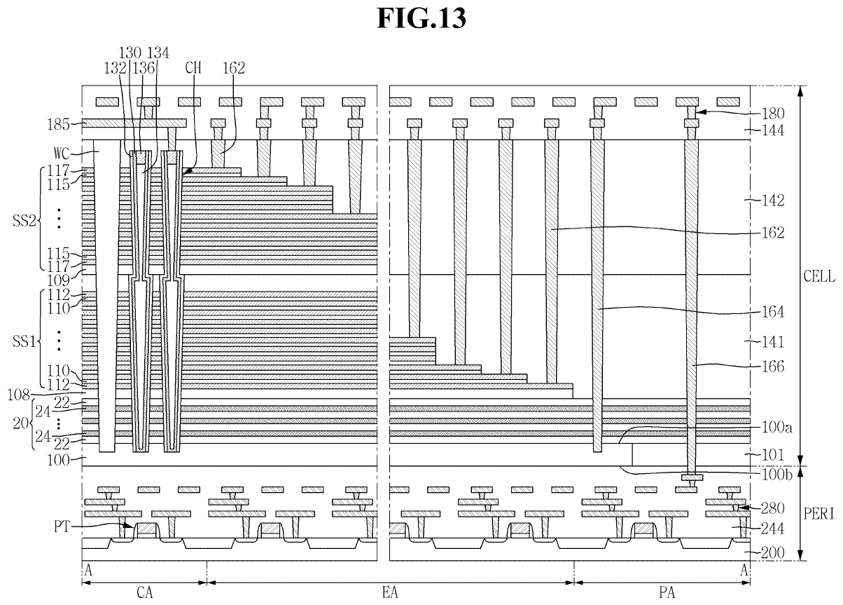

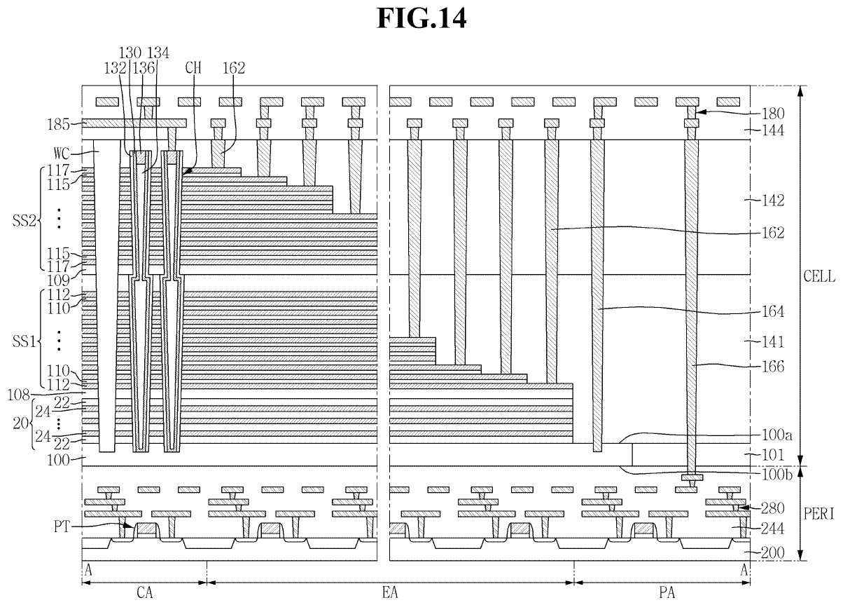

FIGS. 13 and 14 are various cross-sectional views illustrating a semiconductor device according to some embodiments. For convenience of description, redundant portions of those described above with reference to FIGS. 1 to 12 will be briefly described or omitted. Referring to FIG. 13, in the semiconductor device according to some embodiments, the reflective structure 20 is disposed in the cell array area CA, the extension area EA and the outer area PA.

For example, the reflective structure 20 may overlap the insulating substrate 101 of the outer area PA. Although the reflective structure 20 is shown as completely covering the cell array area CA, the extension area EA and the outer area PA, it is only example. As another example, the reflective structure 320 may be disposed in a portion of the cell array area CA, a portion of the extension area EA and/or a portion of the outer area PA. In some embodiments, the source contact 164 may be connected to the first substrate 100 by passing through the reflective structure 20. In some embodiments, the through via 166 may be connected to the second wiring structure 280 by passing through the reflective structure 20.

Referring to FIG. 14, in the semiconductor device according to some embodiments, at least one second reflective layer 24 is formed at the same level as the gate electrodes 112 and 117. In the present disclosure, the term “same level” means that it is formed by the same fabricating process. For example, at least one second reflective layer 24 may include the same material as those of the gate electrodes 112 and 117. Alternatively, a material configuration of the at least one second reflective layer 24 may be the same as that of the gate electrodes 112 and 117. For example, at least one first reflective layer 22 may include a silicon oxide film, and at least one second reflective layer 24 may include a conductive material, for example, metal such as tungsten (W), molybdenum (Mo), ruthenium (Ru), cobalt (Co), nickel (Ni) or the like or a semiconductor material such as silicon.

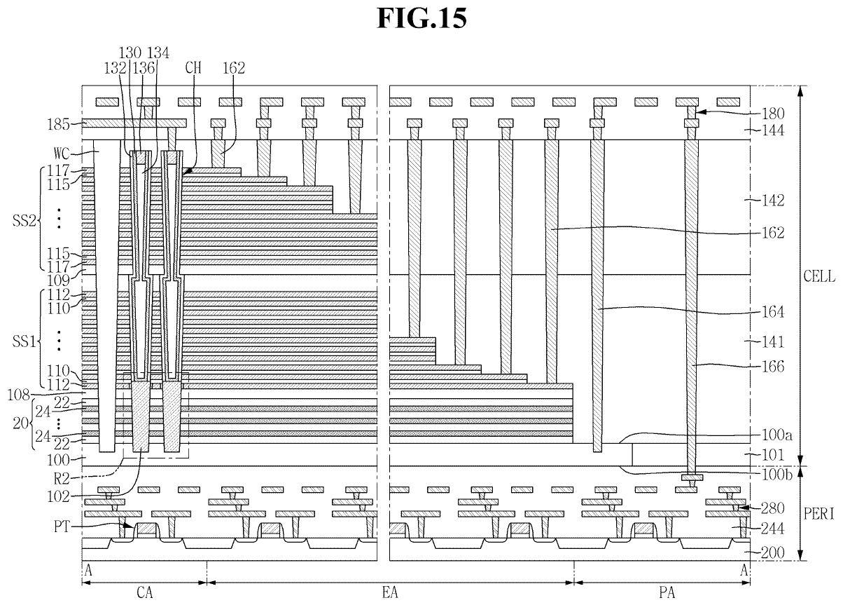

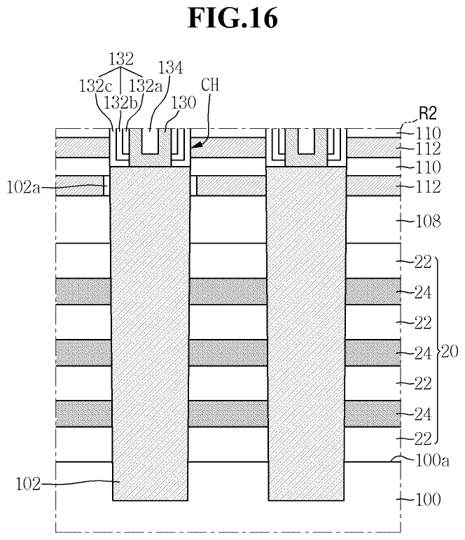

FIG. 15 is a cross-sectional view illustrating a semiconductor device according to some embodiments. FIG. 16 is an enlarged view illustrating a region R2 of FIG. 15. For convenience of description, redundant portions of those described above with reference to FIGS. 1 to 14 will be briefly described or omitted. Referring to FIGS. 15 and 16, in the semiconductor device according to some embodiments, the channel structure CH further includes a source pattern 102. The source pattern 102 may be formed on the first substrate 100. The source pattern 102 may be interposed between the first substrate 100 and the semiconductor film 130 and between the first substrate 100 and the data storage film 132. The source pattern 102 may be electrically connected to the semiconductor film 130. For example, one end (e.g., lower end) of the semiconductor film 130 may be in contact with the source pattern 102 by passing through a lower portion of the data storage film 132. The source pattern 102 may include a conductive material, for example, polysilicon doped with impurities, metal or metal silicide, but is not limited thereto. In some embodiments, the source pattern 102 may be formed by a selective epitaxial growth process from the first substrate 100. The first substrate 100 and the source pattern 102 may be provided as the common source line (e.g., CSL of FIG. 9) of the semiconductor device according to some embodiments.

In some embodiments, the source pattern 102 may pass through the reflective structure 20. In some embodiments, the source pattern 102 may cross a portion of the first gate electrodes 112. For example, an upper surface of the source pattern 102 may be formed to be higher than an upper surface of the erase control line (ECL of FIG. 9; for example, a gate electrode disposed at a lowermost portion of the first gate electrodes 112). The source pattern 102 may be spaced apart from the erase control line by a side insulating film 102a.

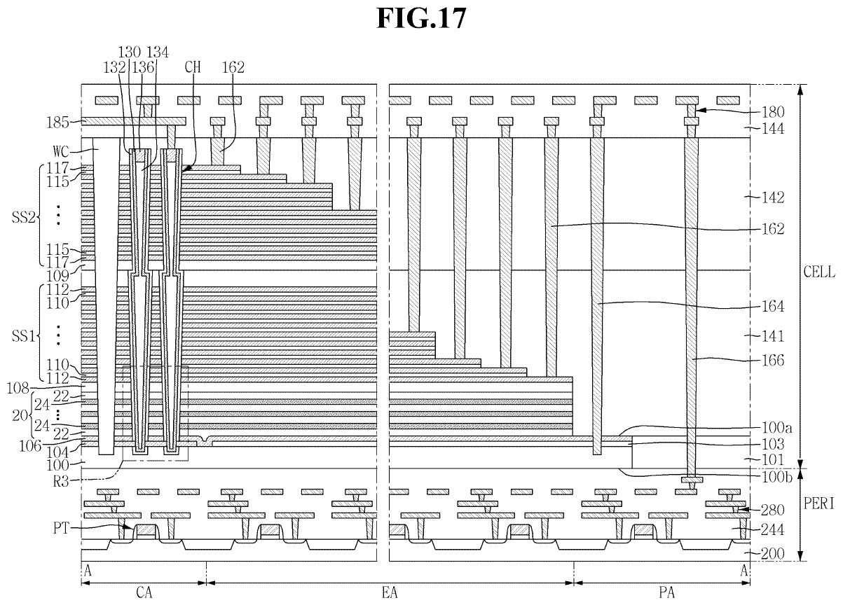

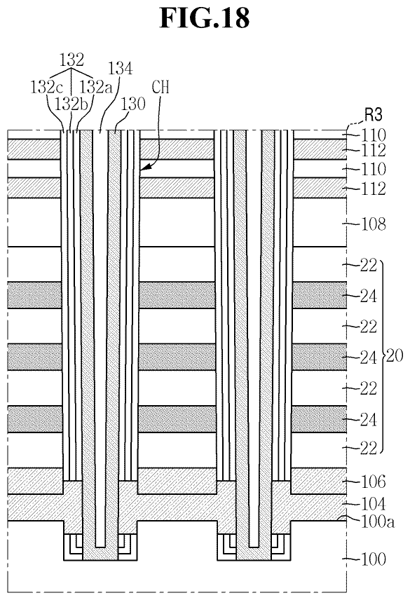

FIG. 17 is a cross-sectional view illustrating a semiconductor device according to some embodiments. FIG. 18 is an enlarged view illustrating a region R3 of FIG. 17. For convenience of description, redundant portions of those described above with reference to FIGS. 1 to 14 will be briefly described or omitted. Referring to FIGS. 17 and 18, a semiconductor device according to some embodiments further includes a source sacrificial layer 103, a source layer 104 and a source support layer 106. The source layer 104 may be formed on the first surface 100a of the first substrate 100. The source layer 104 may be interposed between the first substrate 100 and the stacked structures SS1 and SS2. For example, the source layer 104 may be extended to be conformal along the first surface 100a of the first substrate 100. The source layer 104 may be electrically connected to the semiconductor film 130. For example, the source layer 104 may be in contact with a side of the semiconductor film 130 by passing through the data storage film 132. In some embodiments, the source layer 104 may be formed on the first substrate 100 of the cell array area CA, and may not be formed on the first substrate 100 of the extension area EA.

The source layer 104 may include a conductive material, for example, polysilicon doped with impurities, metal or metal silicide, but is not limited thereto. The first substrate 100 and the source layer 104 may be provided as the common source line (e.g., CSL of FIG. 9) of the semiconductor device according to some embodiments.

The source sacrificial layer 103 may be formed on the first substrate 100 of the extension area EA and/or the first substrate 100 of the outer area PA. The source sacrificial layer 103 may be disposed at the same level as the source layer 104. In the present disclosure, the term “same level” means that it is disposed at the same height based on the upper surface of the first substrate 100. For example, a lower surface of the source sacrificial layer 103 may be disposed at the same height as a lower surface of the source layer 104.

The source sacrificial layer 103 may be a remaining layer after a portion thereof is replaced with the source layer 104. In this case, a thickness of the source layer 104 may be the same as a thickness of the source sacrificial layer 103. For example, an upper surface of the source sacrificial layer 103 may be disposed at the same height as the upper surface of the source layer 104. The source sacrificial layer 103 may include at least one of an insulating material, for example, silicon oxide, silicon nitride or silicon oxynitride, but is not limited thereto. In some embodiments, the source sacrificial layer 103 may include a material having etch selectivity with respect to the mold insulating films 110 and 115. For example, each of the mold insulating films 110 and 115 may include a silicon oxide film, and the source sacrificial layer 103 may include a silicon nitride film.

The source support layer 106 may be formed on the first substrate 100, the source layer 104 and the source sacrificial layer 103. For example, the source support layer 106 may be extended to be conformal along the upper surface of the first substrate 100, the upper surface of the source layer 104 and the upper surface of the source sacrificial layer 103. The source support layer 106 may include a material having etch selectivity with respect to the source sacrificial layer 103. For example, the source sacrificial layer 103 may include a silicon nitride film, and the source support layer 106 may include a polysilicon film. In some embodiments, the first substrate 100, the source layer 104 and the source support layer 106 may be provided as the common source line (e.g., CSL of FIG. 9) of the semiconductor device according to some embodiments.

The source support layer 106 may be used as a support for preventing the mold stack from being collapsed or fallen during a replacement process for forming the source layer 104. For example, the source layer 104 and/or the source sacrificial layer 103 may expose a portion of the upper surface of the first substrate 100, and a portion of the source support layer 106 may be extended along the exposed upper surface of the first substrate 100 to contact the upper surface of the first substrate 100. In some embodiments, the source sacrificial layer 103, the source layer 104 and the source support layer 106 may be interposed between the first substrate 100 and the reflective structure 20. For example, the reflective structure 20 may cover at least a portion of an upper surface of the source support layer 106.

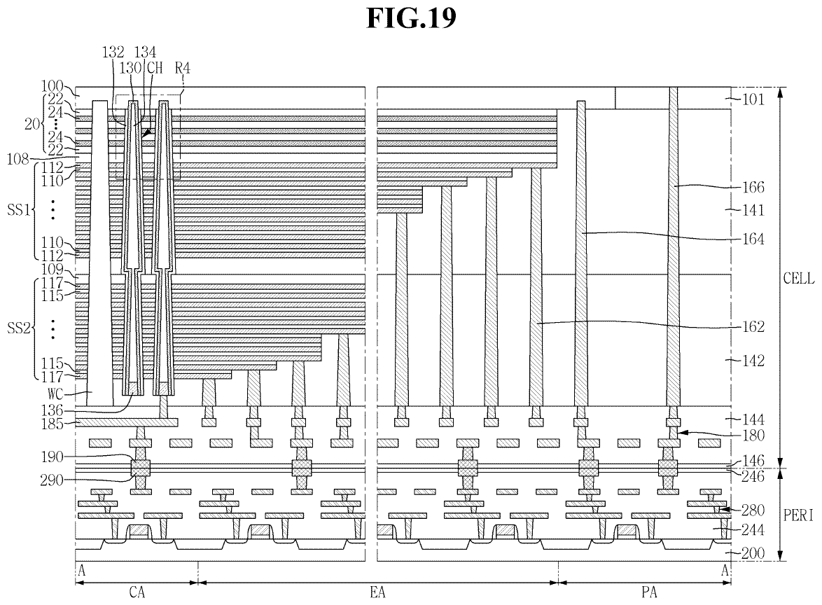

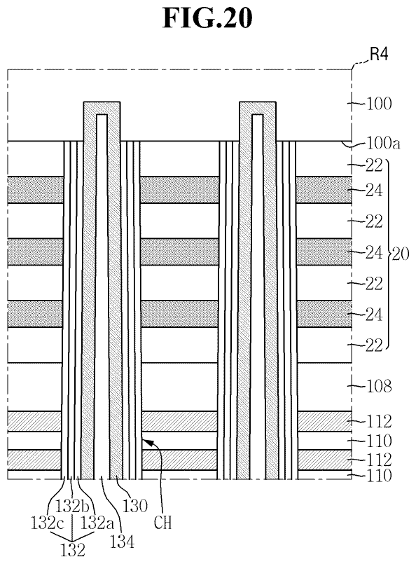

FIG. 19 is a cross-sectional view illustrating a semiconductor device according to some embodiments. FIG. 20 is an enlarged view illustrating a region R4 of FIG. 19. For convenience of description, redundant portions of those described above with reference to FIGS. 1 to 14 will be briefly described or omitted. Referring to FIGS. 19 and 20, in the semiconductor device according to some embodiments, the first surface 100a of the first substrate 100 faces the peripheral circuit structure PERI.

For example, the semiconductor device according to some embodiments may have a chip to chip (C2C) structure. The C2C structure means that an upper chip including a memory cell structure CELL is fabricated on a first wafer, a lower chip including a peripheral circuit structure PERI is fabricated on a second wafer different from the first wafer and then the upper chip and the lower chip are connected to each other by a bonding method.

For example, the bonding method may mean a method of connecting a first bonding metal 190 (and/or a first bonding insulating film 146) formed on the uppermost metal layer of the upper chip and a second bonding metal 290 (and/or a second bonding insulating film 246) formed on the uppermost metal layer of the lower chip to each other. For example, when the first bonding metal 190 and the second bonding metal 290 are formed of copper (Cu), the bonding method may be a Cu—Cu bonding method, but this is only example. The first bonding metal 190 and the second bonding metal 290 may be formed of various other metals such as aluminum (Al) or tungsten (W). As the first bonding metal 190 and the second bonding metal 290 are bonded to each other, the first wiring structure 180 may be electrically connected to the second wiring structure 280. Therefore, the plurality of memory cells formed in the cell array area CA may be electrically connected to the peripheral circuit element PT.

In some embodiments, the channel structure CH may be protruded above the upper surface of the reflective structure 20. For example, one end (e.g., upper end) of the semiconductor film 130 may be formed to be higher than the upper surface of the first reflective layer 22 disposed on the uppermost portion of the reflective structure 20. The semiconductor film 130 may reduce contact resistance by improving a contact area with the first substrate 100.

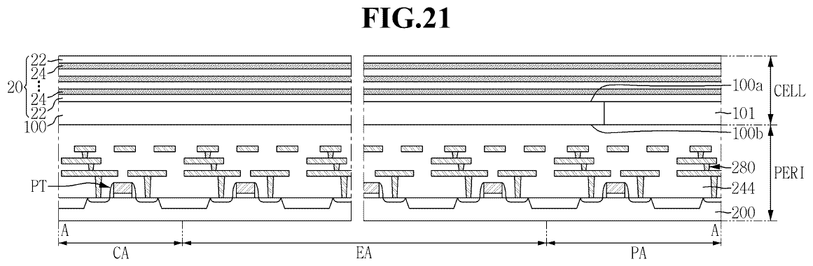

Hereinafter, a method for fabricating a semiconductor memory device according to embodiments will be described with reference to FIGS. 8 to 30. FIGS. 21 to 30 are views illustrating intermediate steps to describe a method for fabricating a semiconductor device according to some embodiments. For convenience of description, redundant portions of those described above with reference to FIGS. 1 to 20 will be briefly described or omitted.

Referring to FIG. 21, a reflective structure 20 is formed on the first substrate 100 and/or the insulating substrate 101. The reflective structure 20 may have a multi-layered structure in which at least one first reflective layer 22 and at least one second reflective layer 24 are alternately stacked, wherein the first and second reflective layers 22 and 24 have their respective indexes different from each other. For example, at least one first reflective layer 22 may include a silicon oxide film, and at least one second reflective layer 24 may include a silicon nitride film.

In some embodiments, the first substrate 100 and/or the insulating substrate 101 may be stacked on the peripheral circuit structure PERI. For example, the peripheral circuit element PT, the second wiring structure 280 and the second inter-wiring insulating film 244 may be formed on the second substrate 200. The first substrate 100 and/or the insulating substrate 101 may be stacked on the second inter-wiring insulating film 244.

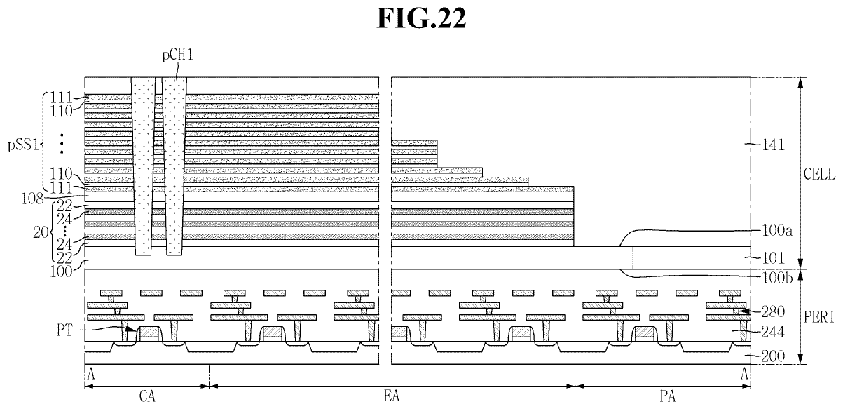

Referring to FIG. 22, a first base insulating film 108, a first preliminary stack pSS1 and a first preliminary channel pCH1 are formed on the reflective structure 20. The first base insulating film 108 and the first preliminary stack pSS1 may be sequentially stacked on the reflective structure 20. The first preliminary stack pSS1 may include a plurality of first mold insulating films 110 and a plurality of first mold sacrificial layers 111, which are alternately stacked on the first base insulating film 108. The first mold sacrificial layers 111 may include a material having etch selectivity with respect to the first mold insulating films 110. For example, each of the first mold insulating films 110 may include a silicon oxide film, and each of the first mold sacrificial layers 111 may include a silicon nitride film.

In some embodiments, the reflective structure 20 may be patterned. For example, the reflective structure 20 on the first substrate 100 in the outer area PA may be removed. In alternative embodiments, the reflective structure 20 may not be patterned.

The first preliminary channel pCH1 may pass through the first base insulating film 108 and the first preliminary stack pSS1. Also, the first preliminary channel pCH1 may be connected to the first substrate 100 by passing through the reflective structure 20. For example, a first interlayer insulating film 141 covering the reflective structure 20 and the first preliminary stack pSS1 may be formed on the first substrate 100. Subsequently, the first preliminary channel pCH1 passing through the first interlayer insulating film 141, the first preliminary stack pSS1 and the reflective structure 20 may be formed. The first preliminary channel pCH1 may include a material having etch selectivity with respect to the reflective structure 20 and the first preliminary stack pSS1. For example, the first preliminary channel pCH1 may include polysilicon (polySi).

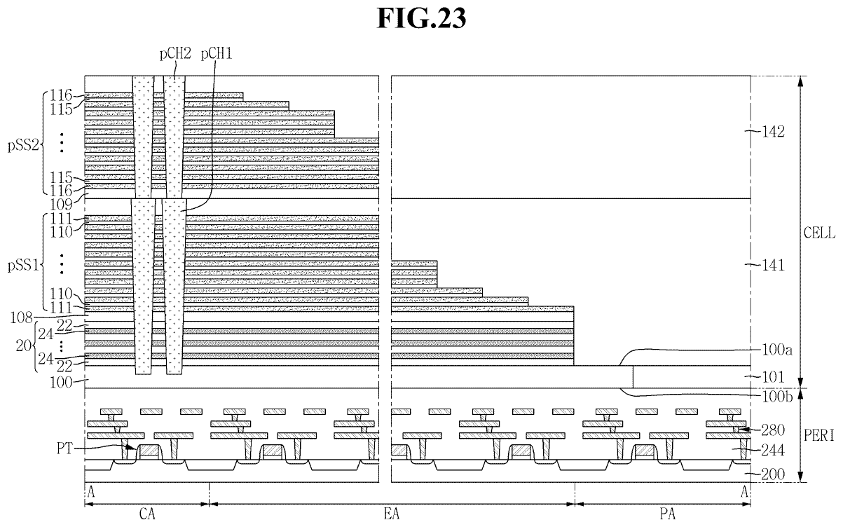

Referring to FIG. 23, a second base insulating film 109, a second preliminary stack pSS2 and a second preliminary channel pCH2 are formed on the first interlayer insulating film 141. The second base insulating film 109 and the second preliminary stack pSS2 may be sequentially stacked on the first interlayer insulating film 141. The second preliminary stack pSS2 may include a plurality of second mold insulating films 115 and a plurality of second mold sacrificial layers 116, which are alternately stacked on the second base insulating film 109. Since the second preliminary stack pSS2 may be formed to be similar to the first preliminary stack pSS1, its detailed description will be omitted below. The second preliminary channel pCH2 may pass through the second base insulating film 109 and the second preliminary stack pSS2. Also, the second preliminary channel pCH2 may be connected to the first preliminary channel pCH1. Since the second preliminary channel pCH2 may be formed to be similar to the first preliminary channel pCH1, its detailed description will be omitted below.

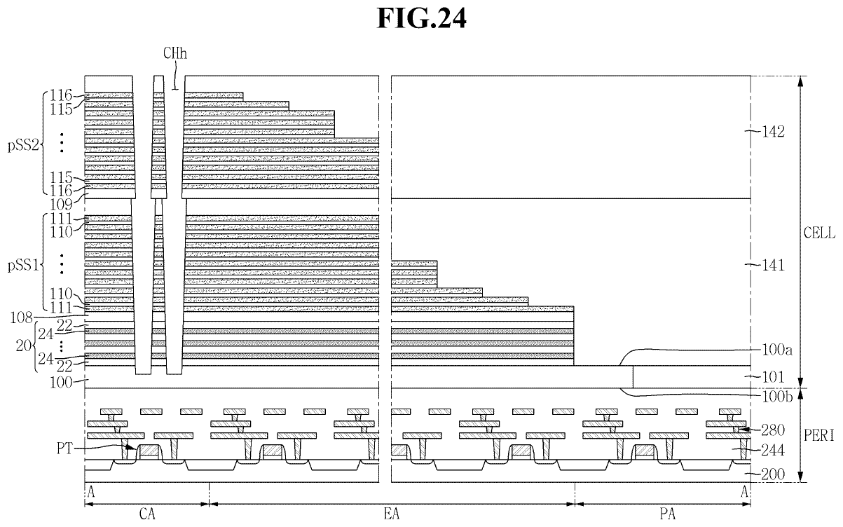

Referring to FIG. 24, a channel hole CHh is formed. For example, the first preliminary channel pCH1 and the second preliminary channel pCH2 may be selectively removed. Therefore, the channel hole CHh passing through the reflective structure 20, the first preliminary stack pSS1 and the second preliminary stack pSS2 may be formed. The channel hole CHh may expose a portion of the first substrate 100.

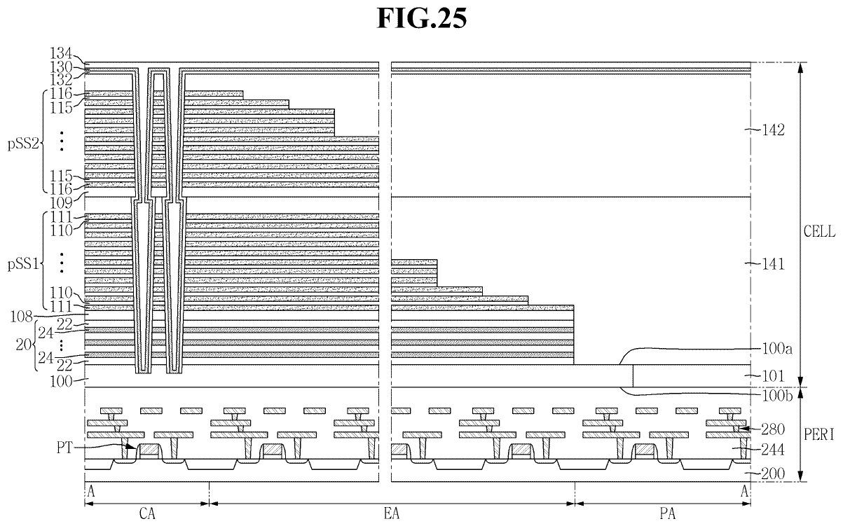

Referring to FIG. 25, the data storage film 132, the semiconductor film 130 and the filling insulating film 134 are formed. The data storage film 132, the semiconductor film 130 and the filling insulating film 134 may fill the channel hole CHh of FIG. 24. For example, the data storage film 132, the semiconductor film 130 and the filling insulating film 134 may be sequentially deposited on the resultant product of FIG. 24.

In some embodiments, the lower end of the semiconductor film 130 may be in contact with the first substrate 100. For example, after the data storage film 132 is deposited, the data storage film 132 may be patterned such that a portion of the first substrate 100 is exposed. Subsequently, the semiconductor film 130 and the filling insulating film 134 may be sequentially deposited on the patterned data storage film 132.

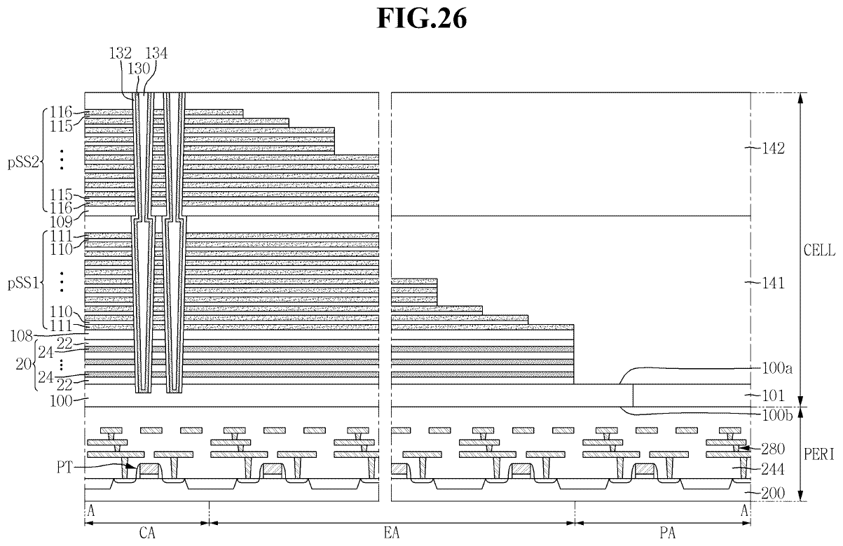

Referring to FIG. 26, a portion of the semiconductor film 130 on the upper surface of the second interlayer insulating film 142 is removed. For example, a planarization process such as a chemical mechanical polishing process may be performed. As the planarization process is performed, the data storage film 132, the semiconductor film 130 and the filling insulating film 134 on the upper surface of the second interlayer insulating film 142 may be removed, and the upper surface of the second interlayer insulating film 142 may be exposed.

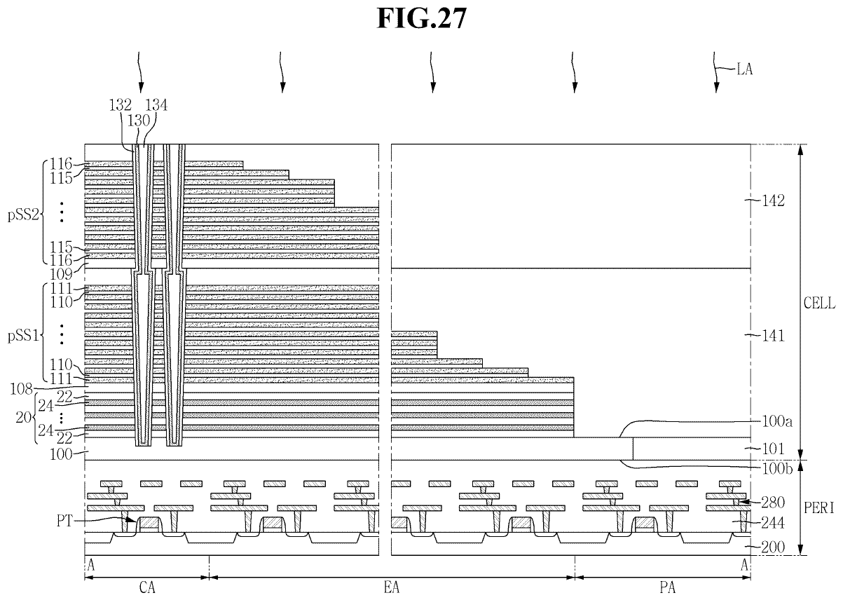

Referring to FIG. 27, a laser annealing process LA for the semiconductor film 130 is performed. As the laser annealing process LA is performed, crystallization of the semiconductor film 130 may be induced, or impurities included in the semiconductor film 130 may be activated. Unlike a general annealing process, since the laser annealing process LA may be locally performed for the semiconductor film 130, damage to the semiconductor device may be minimized.

Also, as described above, the reflective structure 20 may prevent a laser from being absorbed into the first substrate 100 by blocking the laser incident on the first substrate 100 during the laser annealing process LA, and may improve the light absorption rate below the semiconductor film 130 by reflecting the laser toward the semiconductor film 130. Therefore, the method for fabricating a semiconductor device with improved yield and reliability may be provided. Also, as described above, the laser annealing process LA may be performed after a portion of the semiconductor film 130 on the upper surface of the second interlayer insulating film 142 is removed. Therefore, the laser may be absorbed into the semiconductor film 130 on the upper surface of the second interlayer insulating film 142 during the laser annealing process LA.

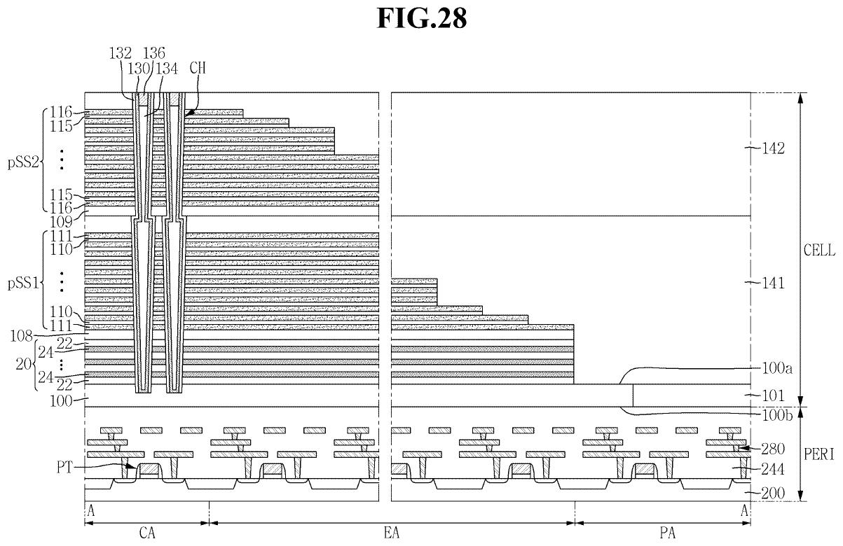

Referring to FIG. 28, a channel pad 136 is formed. For example, an upper portion of the filling insulating film 134 may be removed. Subsequently, the channel pad 136 that replaces the area from which the filling insulating film 134 is removed may be formed. Therefore, the channel pad 136 that is in contact with the upper end of the semiconductor film 130 may be formed.

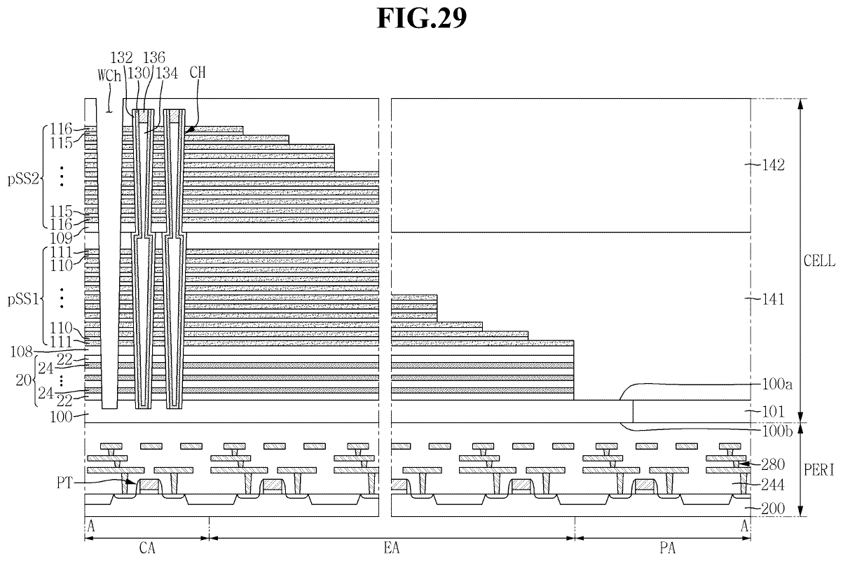

Referring to FIG. 29, a cutting area WCh is formed. The cutting area WCh may be extended in the first direction X to cut the first preliminary stack pSS1 and the second preliminary stack pSS2.

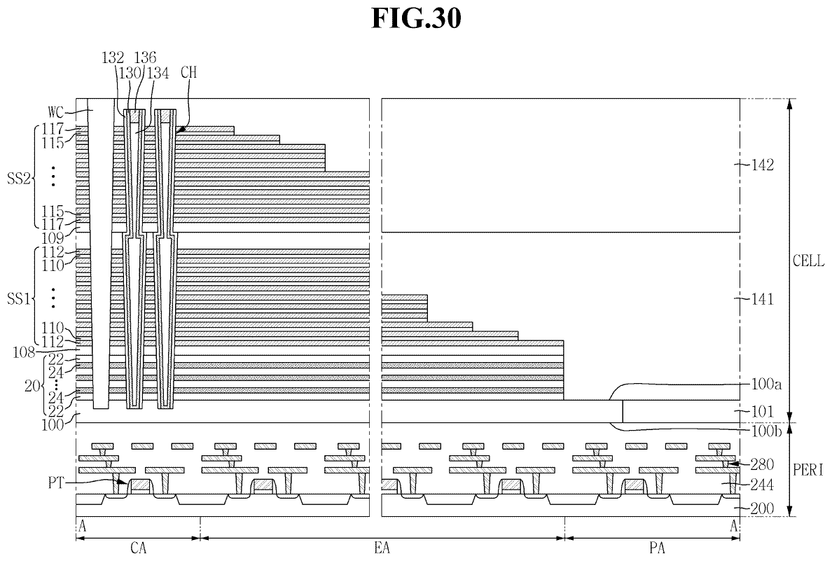

Referring to FIG. 30, a plurality of gate electrodes 112 and 117 are formed. For example, the mold sacrificial layers 111 and 116 exposed by the cutting area WCh may be selectively removed. Subsequently, the gate electrodes 112 and 117 that replace the areas from which the mold sacrificial layers 111 and 116 are removed may be formed. As a result, the stacked structures SS1 and SS2 including the mold insulating films 110 and 115 and the gate electrodes 112 and 117 may be formed. In some embodiments, after the stacked structures SS1 and SS2 are formed, the cutting area WCh may be filled with an insulating material. As a result, a cutting pattern WC for cutting the stacked structures SS1 and SS2 may be formed.

In some embodiments, at least one second reflective layer 24 may remain while the mold sacrificial layers 111 and 116 are removed. For example, the physical properties of the silicon nitride film included in at least one second reflective layer 24 may be different from those of the silicon nitride film included in the mold sacrificial layers 111 and 116. For example, a nitrogen ratio of the silicon nitride film included in at least one second reflective layer 24 may be different from a nitrogen ratio of the silicon nitride film included in the mold sacrificial layers 111 and 116. Therefore, at least one second reflective layer 24 described above with reference to FIG. 11 may be provided.

In some embodiments, at least one second reflective layer 24 may be removed together while the mold sacrificial layers 111 and 116 are removed. For example, the physical properties of the silicon nitride film included in at least one second reflective layer 24 may be the same as the physical properties of the silicon nitride film included in the mold sacrificial layers 111 and 116. Therefore, at least one second reflective layer 24 described above with reference to FIG. 14 may be provided.

Next, referring again to FIG. 11, a first inter-wire insulating film 144 and a first wiring structure 180 are formed on the second interlayer insulating film 142. Therefore, the semiconductor device described with reference to FIGS. 8 to 12 may be fabricated.

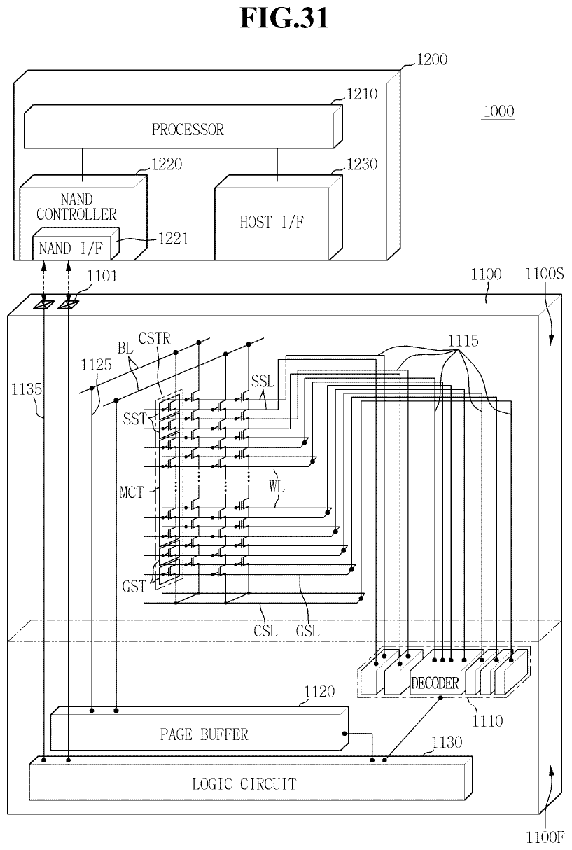

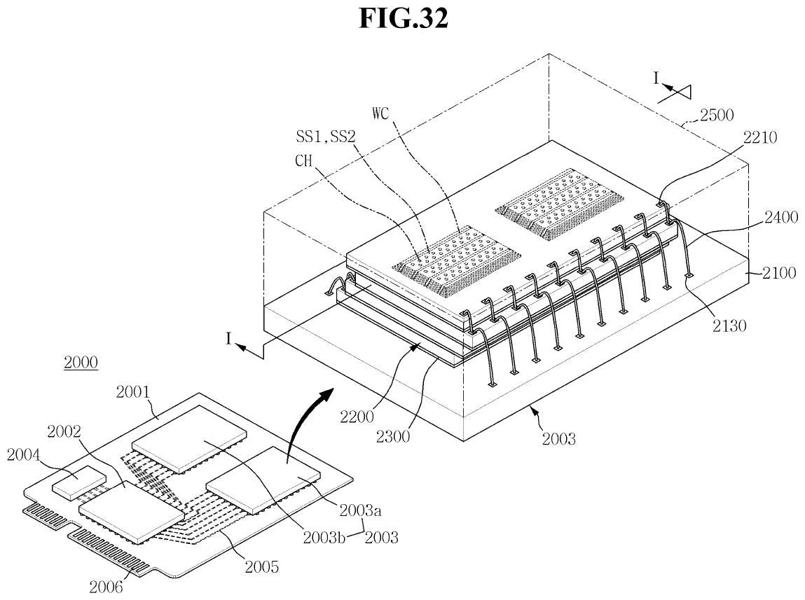

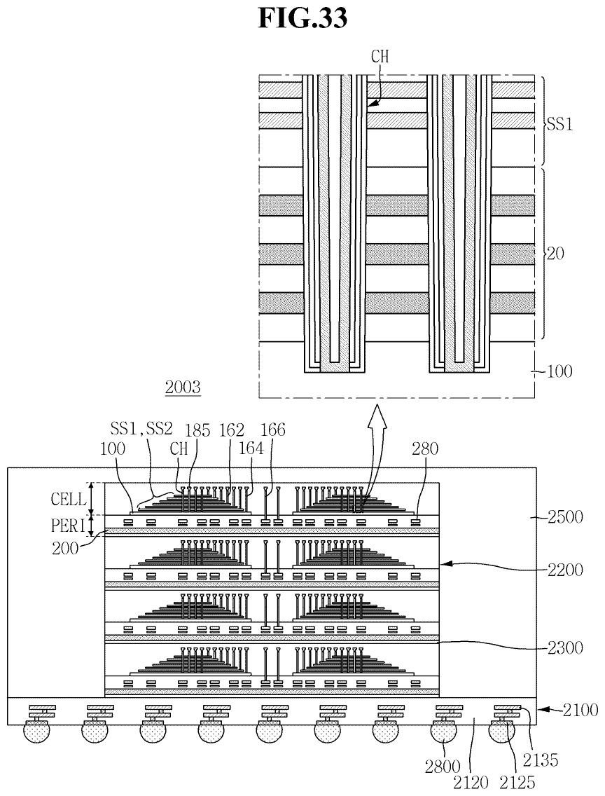

Hereinafter, an electronic system including a semiconductor memory device according to example embodiments will be described with reference to FIGS. 8 to 33. FIG. 31 is an example block diagram illustrating an electronic system according to some embodiments. FIG. 32 is an example perspective view illustrating an electronic system according to some embodiments. FIG. 33 is a schematic cross-sectional view taken along line I-I of FIG. 32.

Referring to FIG. 31, an electronic system 1000 according to some embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive (SSD) device, a universal serial bus (USB), a computing system, a medical device or a communication device, which includes one or more semiconductor memory devices 1100.

The semiconductor memory device 1100 may be a non-volatile memory device (e.g., NAND flash memory device), and include, for example, at least one of the semiconductor memory devices described with reference to FIGS. 8 to 20. The semiconductor memory device 1100 may include a first structure 1100F and a second structure 1100S on the first structure 1100F. The first structure 1100F may be a peripheral circuit structure that includes a decoder circuit 1110 (e.g., row decoder 33 of FIG. 8), a page buffer 1120 (e.g., page buffer 35 of FIG. 1) and a logic circuit 1130 (e.g., control logic 37 o FIG. 1). For example, the first structure 1100F may correspond to the peripheral circuit structure PERI described above with reference to FIGS. 8 to 20.

The second structure 1100S may include a common source line CSL, a plurality of bit lines BL and a plurality of cell strings CSTR, which are described above with reference to FIG. 9. The cell strings CSTR may be connected to the decoder circuit 1110 through a word line WL, at least one string selection line SSL and at least one ground selection line GSL. In addition, the cell strings CSTR may be connected to the page buffer 1120 through the bit lines BL. For example, the second structure 1100S may correspond to the cell structure CELL described above with reference to FIGS. 8 to 20.

In some embodiments, the common source line CSL and the cell strings CSTR may be electrically connected to the decoder circuit 1110 through first connection lines 1115 extended from the first structure 1100F to the second structure 1100S. In some embodiments, the bit lines BL may be electrically connected to the page buffer 1120 through second connection lines 1125.

The semiconductor memory device 1100 may perform communication with the controller 1200 through an input/output pad 1101 electrically connected to the logic circuit 1130 (e.g., the control logic 37 of FIG. 8). The input/output pad 1101 may be electrically connected to the logic circuit 1130 through an input/output connection line 1135 extended from the first structure 1100F to the second structure 1100S. The connection line 1135 may correspond to the through via 166 described above with reference to FIGS. 8 to 20.

The controller 1200 may include a processor 1210, a NAND controller 1220 and a host interface 1230. In some embodiments, the electronic system 1000 may include a plurality of semiconductor memory devices 1100, and in this case, the controller 1200 may control the plurality of semiconductor memory devices 1100. The processor 1210 may control the overall operation of the electronic system 1000 including the controller 1200. The processor 1210 may operate in accordance with predetermined firmware, and may access the semiconductor memory device 1100 by controlling the NAND controller 1220. The NAND controller 1220 may include a NAND interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 32 and 33, an electronic system according to some embodiments may include a main board 2001, a main controller 2002 packaged on the main board 2001, one or more semiconductor packages 2003 and a DRAM 2004. The semiconductor package 2003 and the DRAM 2004 may be connected to the main controller 2002 by wiring patterns 2005 formed in the main board 2001.

The main board 2001 may include a connector 2006 that includes a plurality of pins coupled to the external host. The number and arrangement of the plurality of pins in the connector 2006 may be varied depending on the communication interface between the electronic system 2000 and the external host. In some embodiments, the electronic system 2000 may perform communication with the external host in accordance with any one of interfaces such as a Universal Serial Bus (USB), a Peripheral Component Interconnect Express (PCI-Express), Serial Advanced Technology Attachment (SATA) and M-Phy for Universal Flash Storage (UFS). In some embodiments, the electronic system 2000 may operate by a power source supplied from the external host through the connector 2006. The electronic system 2000 may further include a power management integrated circuit (PMIC) that distributes the power source supplied from the external host to the main controller 2002 and the semiconductor package 2003. The main controller 2002 may write data in the semiconductor package 2003 or read the data from the semiconductor package 2003, and may improve the operating speed of the electronic system 2000.

The DRAM 2004 may be a buffer memory for mitigating a speed difference between the semiconductor package 2003 that is a data storage space and the external host. Also, the DRAM 2004 included in the electronic system 2000 may operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100. The package substrate 2100 may be a printed circuit board that includes package upper pads 2130. Each semiconductor chip 2200 may include an input/output pad 2210. The input/output pad 2210 may correspond to the input/output pad 1101 of FIG. 31.

In some embodiments, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connection structure that includes a through silicon via TSV, instead of the connection structure 2400 of the bonding wire manner.

In some embodiments, the main controller 2002 and the semiconductor chips 2200 may be included in one package. In some embodiments, the main controller 2002 and the semiconductor chips 2200 may be packaged on a separate interposer substrate different from the main board 2001, and the main controller 2002 may be connected with the semiconductor chips 2200 by a wire formed in the interposer substrate.

In some embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface and internal wires 2135 electrically connecting the upper pads 2130 with the lower pads 2125 inside the package substrate body portion 2120. The upper pads 2130 may be electrically connected to the connection structures 2400. The lower pads 2125 may be connected to the wiring patterns 2005 of the main board 2001 of the electronic system 2000 through conductive connectors 2800 as shown in FIG. 32.

In the electronic system according to some embodiments, each of the semiconductor chips 2200 may include the semiconductor memory device described with reference to FIGS. 8 to 20. For example, each of the semiconductor chips 2200 may include a peripheral circuit structure PERI and a memory cell structure CELL stacked on the peripheral circuit structure PERI. Illustratively, the memory cell structure CELL may include the cell substrate 100, the reflective structure 20, the stacked structures SS1 the SS2, the channel structure CH, the cutting pattern WC, the gate contact 162, the source contact 164, the through via 166 and the conductive line 185, which are described with reference to FIGS. 8 to 20. Also, the peripheral circuit structure PERI may include the second substrate 200, the peripheral circuit element PT and the second wiring structure 280, which are described with reference to FIGS. 8 and 20.

Although embodiments of the present disclosure have been described with reference to the accompanying drawings, the present disclosure is not limited to the above embodiments but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A method of forming an integrated circuit device, comprising:
forming a first substrate;
forming a stacked structure including a plurality of spaced-apart gate electrodes sequentially stacked in a first direction, on the first substrate;
forming a reflective structure including at least one first reflective layer having a first refractive index and at least one second reflective layer having a second refractive index unequal to the first refractive index, which are alternately stacked in the first direction and extend between the first substrate and the stacked structure; and
forming a channel structure that extends in the first direction and passes through the stacked structure and the reflective structure, and is connected to the first substrate.

2. The method of claim 1, wherein the at least one first reflective layer has a first thickness in a range from 75 nm to 105 nm, and the at least one second reflective layer has a second thickness in a range from 55 nm to 75 nm.

3. The method of claim 2, wherein the at least one first reflective layer includes a silicon oxide film, and the at least one second reflective layer includes a silicon nitride film.

4. The method of claim 1, wherein the first refractive index is smaller than the second refractive index, and a first thickness of the at least one first reflective layer is greater than a second thickness of the at least one second reflective layer.

5. The method of claim 1, wherein the stacked structure further includes a plurality of mold insulating films alternately stacked with the plurality of spaced-apart gate electrodes; wherein a thickness of the at least one first reflective layer is greater than a thickness of each of the mold insulating films; and wherein a thickness of the at least one second reflective layer is greater than a thickness of each of the spaced-apart gate electrodes.

6. The method of claim 1, wherein the first substrate includes a polysilicon film doped with impurities.

7. The method of claim 1, wherein the channel structure includes a semiconductor film extended in the first direction to cross the plurality of gate electrodes and a data storage film interposed between the plurality of gate electrodes and the semiconductor film.

8. The method of claim 7, wherein the semiconductor film has a thickness in a range from 5 nm to 10 nm.

9. The method of claim 7, wherein the channel structure further includes a source pattern extending between the first substrate and the semiconductor film and between the first substrate and the data storage film; and wherein one end of the semiconductor film is in contact with an upper surface of the source pattern by passing through the data storage film.

10. The method of claim 7, further comprising forming a source layer that extends between the first substrate and the reflective structure, and is in contact with a side of the semiconductor film by passing through the data storage film.

11. The method of claim 1, further comprising forming a peripheral circuit structure including a second substrate and a peripheral circuit element on the second substrate; and wherein the first substrate is stacked on the peripheral circuit structure in the first direction.

12. The method of claim 11, wherein the first substrate includes a first surface facing the peripheral circuit structure and a second surface opposite to the first surface; and wherein the reflective structure and the stacked structure are disposed on the first surface.

13. A method of forming an integrated circuit device, comprising:
forming a substrate;
forming a reflective structure on the substrate, said reflective structure including at least one first reflective layer and at least one second reflective layer that are alternately stacked;
forming a mold layer on the reflective structure; and
forming a semiconductor film that extends in a vertical direction, crosses an upper surface of the substrate, and fills at least a portion of a through hole passing through the mold layer;
wherein a first thickness t1 of the at least one first reflective layer is selected within a range defined by Equation 1 as:
$$\frac{λ}{4 {n}_{1}} - Δ {t}_{1} \leq t 1 \leq \frac{λ}{4 {n}_{1}} + Δ {t}_{1} , where Δ {t}_{1} = \frac{1}{10} ( \frac{λ}{4 {n}_{1}} ) ;$$
wherein a second thickness t2 of the at least one second reflective layer is selected within a range defined by Equation 2 as:
$$\frac{λ}{4 {n}_{2}} - Δ {t}_{2} \leq t 2 \leq \frac{λ}{4 {n}_{2}} + Δ {t}_{2} , where Δ {t}_{2} = \frac{1}{10} ( \frac{λ}{4 {n}_{2}} ) ;$$
and
wherein λ is a wavelength of light in a range from 400 nm to 700 nm during an irradiation of the reflective structure using laser annealing, n₁ represents a refractive index of the at least one first reflective layer, and n₂ represents a refractive index of the at least one second reflective layer.

14. The method of claim 13, wherein the through hole has an aspect ratio of 100 or more.

15. The method of claim 13, wherein the at least one first reflective layer includes at least one of a silicon oxide film or a tetraethyl orthosilicate (TEOS) film; and wherein the at least one second reflective layer includes at least one of a silicon nitride film or a hafnium oxide film.

16. The method of claim 13, wherein the semiconductor film includes a polysilicon film.

17. The method of claim 13, wherein the through hole further passes through the reflective structure.

18. The method of claim 17, wherein the semiconductor film is in contact with the substrate.

19. The method of claim 13, wherein the semiconductor film is not extended along an upper surface of the mold layer.

20. A method of forming an electronic system, comprising:
forming a main board;
forming a semiconductor memory device on the main substrate, said memory device including:
a substrate;
a stacked structure including a plurality of gate electrodes sequentially stacked to be spaced apart from each other in a first direction on the substrate;
a reflective structure including at least one first reflective layer having a first refractive index and at least one second reflective layer having a second refractive index unequal to the first refractive index, which are alternately stacked in the first direction between the substrate and the stacked structure; and
a channel structure extended in the first direction to pass through the stacked structure and the reflective structure, and connected to the substrate; and
forming a controller electrically connected to the semiconductor memory device on the main board.
